(19) United States
(12) Patent Application Publication
(10) Pub. No.: US 2025/0221074 A1
(43) Pub. Date: Jul. 3, 2025

(54) IMAGE SENSOR

(71) Applicant: Samsung Electronics Co., Ltd., Suwon-si (KR)

(72) Inventors: BOSEONG KIM, Suwon-si (KR); Harin Yoo, Suwon-si (KR); Hyunkyu Choi, Suwon-si (KR)

(21) Appl. No.: 18/981,876

(22) Filed: Dec. 16, 2024

(30) Foreign Application Priority Data
Dec. 28, 2023 (KR) 10-2023-0195142

(51) Int. Cl. H10F 39/00

(52) U.S. Cl. CPC H10F 39/8063; H10F 39/807

(57) ABSTRACT

An image sensor including a substrate, first pixels in a first pixel group sharing a first micro-lens; second pixels in a second pixel group sharing a second micro-lens; a first pixel isolation pattern surrounding the first pixels; a second pixel isolation pattern surrounding the second pixels; a first guide pattern between the substrate and the first micro-lens and partially overlapping the first pixel isolation pattern; a second guide pattern between the substrate and the first micro-lens and extending toward a central portion; a third guide pattern between the substrate and the second micro-lens and partially overlapping the second pixel isolation pattern; and a fourth guide pattern between the substrate and the second micro-lens and extending toward a central portion. The width of the second guide pattern in the extension direction of the second guide pattern and the width of the fourth guide pattern in the extension direction are different.

### CROSS-REFERENCE TO RELATED APPLICATION

This application claims priority to and the benefit of Korean Patent Application No. 10-2023-0195142 filed at the Korean Intellectual Property Office on Dec. 28, 2023, the entire contents of which are incorporated herein by reference.

### BACKGROUND

### 1. Field

The present disclosure relates to an image sensor.

### 2. Description of the Related Art

An image sensor is a semiconductor device that converts an optical image to an electrical signal. The image sensor may be classified as one of a charge coupled device (CCD) type image sensor or a complementary metal oxide semiconductor (CMOS) type image sensor, and the CMOS type image sensor is abbreviated as a CMOS image sensor (CIS). The CIS includes a plurality of pixels disposed two-dimensionally, and each pixel includes a photodiode (PD). The photodiode of each pixel serves to convert incident light to an electrical signal.

The pixel may be divided into an anode region that receives light and a cathode region that does not receive light. A micro-lens serves to collect incoming light into the anode region. The micro-lens structure increases sensitivity of the pixel and reduces noise in the pixel.

When a micro-lens is used, an angle of incident light must be included within a predetermined chief ray angle (CRA) for light to reach the anode region. If an angle of incoming light deviates from the CRA, shade may occur in the pixel reducing the intensity. Additionally, light passing through the micro-lens may not reach the anode region depending on a refraction angle and this may reduce the efficiency of the image sensor.

### SUMMARY

Embodiments of the inventive concept provide an image sensor capable of preventing a decrease in the efficiency of a pixel by changing an optical path of the pixel.

However, the problems solved by the embodiments are not limited to the above-described problem and may be variously extended in a range of technical ideas included in the embodiments.

An image sensor according to an embodiment includes: a substrate, a plurality of first pixels that are disposed in a first pixel group and share a first micro-lens; a plurality of second pixels that are disposed in a second pixel group and share a second micro-lens; a first pixel isolation pattern that is disposed on the substrate and surrounds the plurality of first pixels; a second pixel isolation pattern that is disposed on the substrate and surrounds the plurality of second pixels; a first guide pattern that is disposed between the substrate and the first micro-lens and at least partially overlaps the first pixel isolation pattern on a plane parallel to a surface of the substrate; a second guide pattern that is disposed between the substrate and the first micro-lens and extends toward a central portion between the plurality of first pixels on the plane; a third guide pattern that is disposed between the substrate and the second micro-lens and at least partially overlaps the second pixel isolation pattern on the plane; and a fourth guide pattern that is disposed between the substrate and the second micro-lens and extends toward a central portion between the plurality of second pixels on the plane. The width of the second guide pattern in the extension direction of the second guide pattern and the width of the fourth guide pattern in the extension direction of the second guide pattern are different from each other.

According to the embodiments, an image sensor capable of preventing a decrease in the efficiency of the pixel PX by changing an optical path of the pixel may be provided.

It is obvious that the effect of the embodiments is not limited to the above-described effect and may be variously extended without departing from the spirit and scope of the present disclosure.

### BRIEF DESCRIPTION OF THE DRAWINGS

FIG. 1 is a block diagram schematically showing an image sensor according to an embodiment.

FIG. 2 is a plan view showing a portion of the image sensor according to an embodiment.

FIG. 3 is an enlarged view of a portion of FIG. 2.

FIG. 4 is a cross-sectional view cut along a line I-I′ of FIG. 3.

FIG. 5 is a cross-sectional view showing a portion of FIG. 3 cut along a line II-II′.

FIG. 6 is an enlarged view of a portion of FIG. 2.

FIG. 7 is a cross-sectional view cut along a line I-I′ of FIG. 6.

FIG. 8 is a cross-sectional view showing a portion of FIG. 6 cut along a line II-II′.

FIG. 9 is an enlarged view of a portion of FIG. 2.

FIG. 10 is a cross-sectional view cut along a line I-I′ of FIG. 9.

FIG. 11 is a cross-sectional view showing a portion of FIG. 9 cut along a line II-II′.

FIG. 12 is an enlarged view of a portion of FIG. 2.

FIG. 13 is a cross-sectional view cut along a line I-I′ of FIG. 12.

FIG. 14 is a cross-sectional view showing a portion of FIG. 12 cut along a line II-II′.

FIG. 15 is an enlarged view of a portion of FIG. 2.

FIG. 16 is a cross-sectional view cut along a line I-I′ of FIG. 15.

FIG. 17 is a cross-sectional view showing a portion of FIG. 15 cut along a line II-II′.

FIG. 18 is a cross-sectional view cut along the line I-I′ of each of FIGS. 3, 6, 9, 12, and 15.

FIG. 19 is a cross-sectional view cut along the line II-II′ of each of FIG. 6 and FIG. 9.

FIG. 20 is a cross-sectional view cut along the line II-II′ of each of FIG. 12 and FIG. 15.

FIGS. 21, 22, 23, and 24 are enlarged views of a portion of FIG. 2.

FIGS. 25, 26, 27, and 28 are enlarged views of a portion of FIG. 2.

FIGS. 29, 30, 31, and 32 are enlarged views of a portion of FIG. 2.

FIGS. 33, 34, 35, 36, and 37 are enlarged views of a portion of FIG. 2.

FIGS. 38, 39, 40, and 41 are enlarged views of a portion of FIG. 2.

FIGS. 42, 43, 44, and 45 are enlarged views of a portion of FIG. 2.

FIGS. 46, 47, 48, and 49 are enlarged views of a portion of FIG. 2.

### DETAILED DESCRIPTION

The present disclosure will be described more fully hereinafter with reference to the accompanying drawings, in which various embodiments are shown so that those skilled in the art may easily implement the inventive concept. The present disclosure may be modified in various different ways, all without departing from the spirit or scope of the inventive concept.

In order to clearly describe the present disclosure, parts or portions that may be irrelevant to the inventive concept may be omitted and identical or similar constituent elements throughout the specification are denoted by the same reference characters.

Further, the accompanying drawings are provided only to allow the embodiments disclosed in the present specification to be easily understood and are not to be interpreted as limiting the inventive concept, and it is to be understood that the inventive concept includes modifications, equivalents, and substitutions of the present disclosure without departing from the scope and spirit of the inventive concept.

Further, in the drawings, the size and thickness of each element are arbitrarily illustrated for ease of description, and embodiments are not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

Terms such as “central,” “same,” “equal,” “parallel”, “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

A “central portion” refers to an area adjacent to a center line or a center of an area, or a volume adjacent to a central plane or a center point of a volume, depending on the context. When referring to a distance between overlapping central portions, the distance refers to a distance between centerlines, centers, or central planes of the objects.

It will be understood that when an element such as a layer, film, region, area, or substrate is referred to as being “on” or “above” another element, it may be directly on the other element, or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other.

Spatially relative terms, such as “beneath,” “below,” “lower,” “above,” “upper,” “top,” “bottom,” and the like, may be used herein for ease of description to describe positional relationships, such as illustrated in the figures, for example. It will be understood that the spatially relative terms encompass different orientations of the device in addition to the orientation depicted in the figures. Furthermore, the terms “left” and “right” when used in the description of the figures are used for ease of description and are specific to the relative position of elements as viewed in the particular figure. It will be understood that the relative position of the elements with respect to “left” and “right” may appear different when viewed in other figures.

When two or more items are said to be “overlapping” it will be understood that at least a portion of each item occupies the same location as another item when viewed in a plan view (e.g., along a vertical direction), unless otherwise indicated.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Hereinafter, various embodiments and variations will be described in detail with reference to the drawings.

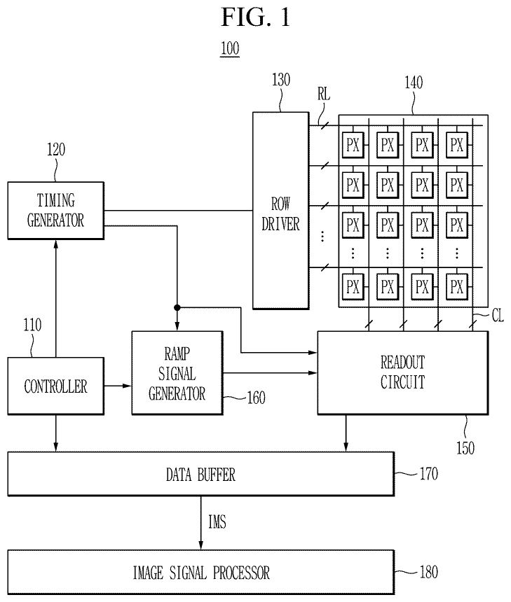

An image sensor according to an embodiment will be schematically described with reference to FIG. 1. FIG. 1 is a block diagram schematically showing the image sensor according to the embodiment.

Referring to FIG. 1, the image sensor 100 according to the embodiment may include a pixel array 140 and a logic circuit that controls the pixel array 140.

The logic circuit may be a circuit for controlling the pixel array 140. For example, the logic circuit may include a controller 110, a timing generator 120, a row driver 130, a readout circuit 150, a ramp signal generator 160, a data buffer 170, and the like.

In addition, the image sensor 100 may further include an image signal processor 180, and according to another embodiment, the image signal processor 180 may be disposed outside the image sensor 100. The image sensor 100 may generate an image signal by converting light received from the outside to an electrical signal. The image signal may be provided to the image signal processor 180.

The image sensor 100 may be mounted on an electronic device having an image or optical sensing function. For example, the image sensor 100 may be mounted on an electronic device such as a camera, a smart phone, a wearable device, an Internet of Things (IoT) device, a home appliance, a tablet personal computer (PC), a navigation device, a drone, an advanced drivers assistance system (ADAS), or the like. In addition, the image sensor 100 may be mounted on an electronic device provided as a component in a vehicle, furniture, manufacturing equipment, a door, various measurement devices, or the like.

The pixel array 140 may include a plurality of pixels PX, and a plurality of row lines RL and a plurality of column lines CL respectively connected to the plurality of pixels PX.

In an embodiment, each pixel PX may include at least one photoelectric conversion element. The photoelectric conversion element may sense incident light and may convert the incident light to an electrical signal according to an amount of light sensed by the photoelectric conversion element. The electrical signal may be referred to as an analog pixel signal. Each analog pixel signal from the plurality of pixels PX may be combined with the analog pixel signal of another photoelectric conversion element.

The photoelectric conversion element may be a photodiode, a pinned diode, or the like. In addition, the photoelectric conversion element may be a single-photon avalanche diode (SPAD) applied to a 3D sensor pixel.

A level of the analog pixel signal output from the photoelectric conversion element may be proportional to an amount of an electric charge output from the photoelectric conversion element. That is, the level of the analog pixel signal output from the photoelectric conversion element may be determined according to an amount of light received by the photoelectric conversion element within the pixel array 140.

The plurality of row lines RL may be connected to the plurality of pixels PX. For example, a control signal output from the row driver 130 to the row line RL may be transferred to gates of transistors of the plurality of pixels PX connected to the corresponding row line RL. The column line CL may be disposed to cross the row line RL and may be connected to the plurality of pixels PX. A plurality of pixel signals output from the plurality of pixels PX may be transferred to the readout circuit 150 through the plurality of column lines CL.

In an embodiment, the plurality of pixels PX may be arranged in a plurality of pixel unit groups. Each pixel unit group may include a plurality of pixels PX which may be arranged in a plurality of columns and a plurality of rows form the unit pixel group. That is, a first plurality of pixels PX arranged in the direction of the column line CL and a second plurality of pixels PX arranged in the direction of the row line RL may constitute one unit pixel group PG. The pixels of the unit pixel group may be adjacent to one another such that no pixels from another unit pixel group are between the pixels of the unit pixel group. For example, a unit pixel group PG may include a first pixel PX and a second pixel PX arranged in a first row and a third pixel PX and a fourth pixel PX arranged in a second row. The first pixel PX and the third pixel PX may be arranged in a first column and the second pixel PX and the fourth pixel PX may be arranged in a second column. The unit pixel group PG may output a single analog pixel signal. However, embodiments are not limited thereto, and numerous variations are possible.

The controller 110 may control the operation timing of each of the above-described components 120, 130, 150, 160, and 170 using control signals.

In an embodiment, the controller 110 may receive a mode signal indicating an imaging mode from an application processor and may generally control the image sensor 100 based on the received mode signal. For example, the application processor may determine the imaging mode of the image sensor 100 according to various scenarios such as illuminance of an imaging environment, a resolution setting of a user, a sensed or learned state, and the like, and may provide the determined result to the controller 110 as the mode signal.

The controller 110 may control the plurality of pixels PX of the pixel array 140 to output a pixel signal according to the imaging mode, the pixel array 140 may generate a pixel signal for each of the plurality of pixels PX or a pixel signal for some of the plurality of pixels PX, and the readout circuit 150 may sample and process pixel signals received from the pixel array 140.

The timing generator 120 may generate a signal serving as a reference for operation timing of components of the image sensor 100. The timing generator 120 may control timing of the row driver 130, the readout circuit 150, and the ramp signal generator 160. The timing generator 120 may provide a control signal for controlling the timing of the row driver 130, the readout circuit 150, and the ramp signal generator 160.

The row driver 130 may generate a control signal for driving the pixel array 140 in response to the control signal of the timing generator 120 and may provide the control signal to the plurality of pixels PX of the pixel array 140 through the plurality of row lines RL.

In an embodiment, the row driver 130 may control the pixels PX to sense incident light in a unit of a row line. The unit of the row line may include at least one row line RL. For example, the row driver 130 may generate a transmission signal for controlling a transmission transistor, a reset control signal for controlling a reset transistor, a selection control signal for controlling a selection transistor, and the like to provide the generated signals to the pixel array 140.

The readout circuit 150 may convert the pixel signal (or an electrical signal) from a pixel PX of the plurality of pixels PX connected to a selected row line RL to a pixel value representing an amount of light in response to the control signal from the timing generator 120.

The readout circuit 150 may convert the pixel signal output through the column line CL to a pixel value. For example, the readout circuit 150 may convert the pixel signal to the pixel value by comparing the pixel signal with a ramp signal. The pixel value may be image data having a plurality of bits. Specifically, the readout circuit 150 may include a selector, a plurality of comparators, a plurality of counter circuits, and the like.

The ramp signal generator 160 may generate a reference signal to transmit the reference signal to the readout circuit 150. The ramp signal generator 160 may include a current source, a resistor, and a capacitor. The ramp signal generator 160 may adjust a current size of a variable current source or a resistance value of a variable resistor to adjust a ramp voltage that is a voltage applied to a ramp resistor. Thus, the ramp signal generator 160 may generate a plurality of ramp signals that fall or rise with a slope determined according to the current size of the variable current source or the resistance value of the variable resistor.

The data buffer 170 may store pixel values of the plurality of pixels PX connected to a selected column line CL transferred from the readout circuit 150 and may output the stored pixel values in response to an enable signal from the controller 110.

The image signal processor 180 may perform image signal processing on the image signal received from the data buffer 170. For example, the image signal processor 180 may receive a plurality of image signals from the data buffer 170 and may synthesize the received image signals to generate one image.

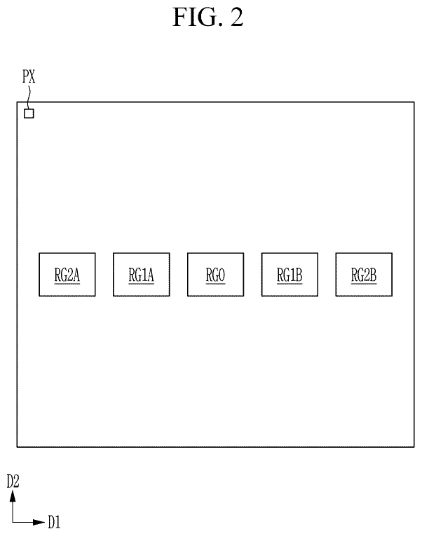

The positioning and arrangement of pixels in an image sensor according to an embodiment will be described with reference to FIG. 2. FIG. 2 is a plan view showing a portion of an image sensor according to an embodiment.

Referring to FIG. 2, a pixel array of the image sensor 100 according to an embodiment may include a plurality of pixels PX disposed along a first direction D1 and a second direction D2. The plurality of pixels PX may be disposed in a matrix form along the first direction D1 and the second direction D2 crossing each other.

The plurality of pixels PX may include a first pixel group RG0 disposed at a central portion of the image sensor 100, a second pixel group RG1A disposed at the left side with respect to the first pixel group RG0, a third pixel group RG1B disposed at the right side with respect to the first pixel group RG0, a fourth pixel group RG2A disposed at the left side of the second pixel group RG1A and adjacent to an edge portion of the image sensor 100, and a fifth pixel group RG2B disposed at the right side of the third pixel group RG1B and adjacent to the edge portion of the image sensor 100 that are disposed along the first direction D1.

Along the first direction D1, the first pixel group RG0 may be disposed at the central portion of the image sensor 100, the fourth pixel group RG2A and the fifth pixel group RG2B may be disposed adjacent to both edges of the image sensor 100, the second pixel group RG1A may be disposed between the first pixel group RG0 and the fourth pixel group RG2A, and the third pixel group RG1B may be disposed between the first pixel group RG0 and the fifth pixel group RG2B.

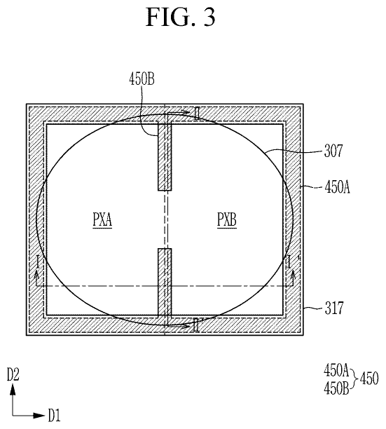

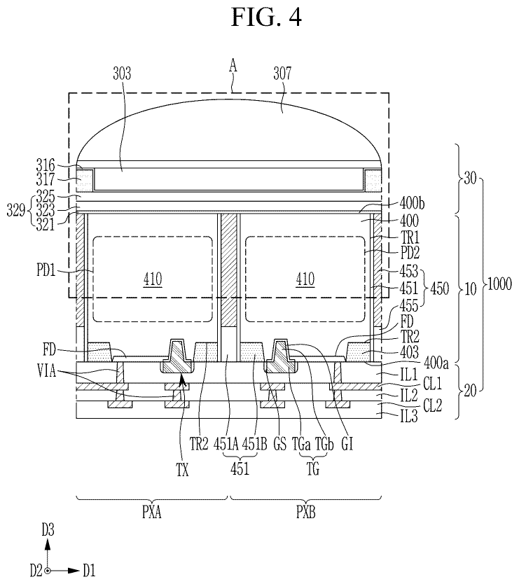

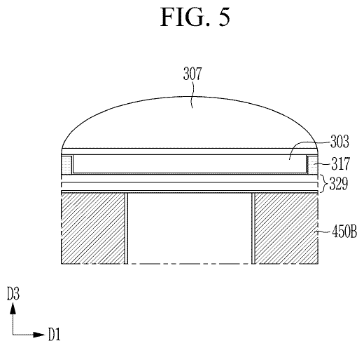

An example of a pixel region within the first pixel group RG0 of the image sensor according to an embodiment will be described with reference to FIGS. 3 to 5. FIG. 3 is an enlarged view of a portion of FIG. 2, FIG. 4 is a cross-sectional view cut along a line I-I′ of FIG. 3, and FIG. 5 is a cross-sectional view showing a portion of FIG. 3 cut along a line II-II′. FIG. 5 shows a portion corresponding to a portion A of FIG. 4.

Referring to FIG. 3, the image sensor according to the embodiment may include a plurality of pixels sharing a micro-lens 307. The plurality of pixels may include a first pixel PXA and a second pixel PXB that are adjacent to each other along the first direction D1. In other embodiments, there may be more than two pixels sharing a micro-lens 307. The first pixel PXA and the second pixel PXB may be separated by a pixel isolation pattern (or a pixel separation pattern) 450. The pixel isolation pattern 450 may surround the first pixel PXA and the second pixel PXB.

The pixel isolation pattern 450 may include a first pixel isolation pattern 450A disposed at an outer portion to surround the first pixel PXA and the second pixel PXB and a second pixel isolation pattern 450B extending from the first pixel isolation pattern 450A along the second direction D2 to be disposed between the first pixel PXA and the second pixel PXB. The second pixel isolation pattern 450B of the pixel isolation pattern 450 may not be disposed at a central portion between the first pixel PXA and the second pixel PXB (e.g., there may be a gap in the second pixel isolation pattern 450B between the first pixel PXA and the second pixel PXB). The pixel isolation pattern 450 may prevent crosstalk between the pixels.

Although not shown in the drawings, the plurality of pixels may include at least one transmission gate, at least one drive gate, at least one selection gate, at least one reset gate, and at least one dual conversion gate.

Referring to FIG. 4 and FIG. 5 together with FIG. 3, the image sensor may include a photoelectric conversion layer 10, a wiring region 20, and a light transmission layer 30.

The photoelectric conversion layer 10 may include a substrate 400 and the pixel isolation pattern 450.

The substrate 400 may include silicon (Si), germanium (Ge), or silicon (Si)-germanium (Ge). The substrate 400 may include gallium arsenic (GaAs), indium phosphorus (InP), gallium phosphorus (GaP), indium arsenic (InAs), indium antimony (InSb), or indium gallium arsenic (InGaAs). The substrate 400 may include zinc telluride (ZnTe) or cadmium sulfide (CdS).

The substrate 400 may include bulk silicon or silicon-on-insulator (SOI). The substrate 400 may be a silicon substrate, or may include another material (for example, silicon germanium, indium antimonide, a lead tellurium compound, indium arsenic, indium phosphide, gallium arsenic, or gallium antimonide). Alternatively, the substrate 400 may be a substrate in which an epitaxial layer is formed on a base substrate.

The substrate 400 may include a first surface 400a and a second surface 400b on opposing sides. Light may be incident on the second surface 400b of the substrate 400.

The substrate 400 may have a first trench TR1 formed therein, and the pixel isolation pattern 450 may be disposed within the first trench TR1. The first trench TR1 may be recessed from the first surface 400a of the substrate 400.

The pixel isolation pattern 450 may surround the pixels PXA and PXB, and the pixels PXA and PXB may be divided by the pixel isolation pattern 450.

As described above, the pixel isolation pattern 450 may not be disposed at a portion of a region between the first pixel PXA and the second pixel PXB that are adjacent to each other and share the micro-lens 307.

The pixel isolation pattern 450 may extend from the first surface 400a of the substrate 400 toward the second surface 400b. The pixel isolation pattern 450 may be a deep trench isolation (DTI) film. The pixel isolation pattern 450 may penetrate completely through the substrate 400. A vertical height of the pixel isolation pattern 450 may be the same as or substantially the same as a vertical thickness of the substrate 400. The width of the pixel isolation pattern 450 may gradually decrease from the first surface 400a of the substrate 400 to the second surface 400b.

The pixel isolation pattern 450 may include a first isolation pattern 451, a second isolation pattern 453, and a capping pattern 455. The first isolation pattern 451 may be disposed along a sidewall of the first trench TR1. The first isolation pattern 451 may include a silicon-based insulating material (e.g., silicon nitride, silicon oxide, or silicon oxynitride) or a high dielectric material (e.g., hafnium oxide or aluminum oxide). The first isolation pattern 451 may include a plurality of layers, and each of the layers may include a different material. The first isolation pattern 451 may have a lower refractive index than that of the substrate 400. Accordingly, a crosstalk phenomenon between the pixels PX may be prevented or reduced.

The second isolation pattern 453 may be disposed within the first isolation pattern 451. For example, a sidewall of the second isolation pattern 453 may be surrounded by the first isolation pattern 451. The first isolation pattern 451 may be disposed between the second isolation pattern 453 and the substrate 400. The second isolation pattern 453 may be spaced apart from the substrate 400 by the first isolation pattern 451. Accordingly, during operation of the image sensor, the second isolation pattern 453 may be electrically separated from the substrate 400. The second isolation pattern 453 may include a crystalline semiconductor material (for example, polycrystalline silicon). The second isolation pattern 453 may further include a dopant, and the dopant may include an impurity of a first conductivity type or an impurity of a second conductivity type.

For example, the second isolation pattern 453 may include doped polycrystalline silicon. Alternatively, the second isolation pattern 453 may include an undoped crystalline semiconductor material. For example, the second isolation pattern 453 may include undoped polycrystalline silicon. The term “undoped” may mean not performing an intentional doping process. The dopant may include an n-type dopant and a p-type dopant.

The capping pattern 455 may be disposed on a lower surface of the second isolation pattern 453. The capping pattern 455 may be disposed adjacent to the first surface 400a of the substrate 400. A lower surface of the capping pattern 455 may be coplanar with the first surface 400a of the substrate 400. An upper surface of the capping pattern 455 may be at the same or substantially the same level as the lower surface of the second isolation pattern 453 and may contact the lower surface of the second isolation pattern 453. The capping pattern 455 may include a non-conductive material. As an example, the capping pattern 455 may include a silicon-based insulating material (e.g., silicon nitride, silicon oxide, or silicon oxynitride) or a high dielectric material (e.g., hafnium oxide or aluminum oxide). Accordingly, the pixel isolation pattern 450 may prevent photo charges generated by incident light incident on the pixel PX from entering another pixel PX adjacent to the pixel PX due to random drift. In other words, the pixel isolation pattern 450 may prevent a crosstalk between the pixels PX.

The substrate 400 may include the plurality of pixels PXA and PXB, which may be defined by the pixel isolation pattern 450.

The substrate 400 may include a photoelectric conversion region 410. The photoelectric conversion region 410 may be a region where photoelectric conversion elements PD1 and PD2 are disposed.

The photoelectric conversion region 410 may be a region doped with a second conductivity type impurity within the substrate 400. The second conductivity type impurity may have a conductivity type opposite to that of a first conductivity type impurity. The second conductivity type impurity may include an n-type impurity such as phosphorus, arsenic, bismuth, and/or antimony. For example, each photoelectric conversion region 410 may include a first region adjacent to the first surface 400a and a second region adjacent to the second surface 400b. There may be a difference in impurity concentration between the first region and the second region of the photoelectric conversion region 410. Therefore, the photoelectric conversion region 410 may have a potential slope between the first surface 400a and the second surface 400b of the substrate 400. As another example, the photoelectric conversion region 410 may not have a potential slope between the first surface 400a and the second surface 400b of the substrate 400.

The substrate 400 and the photoelectric conversion region 410 may form a photodiode.

An element isolation pattern 403 may be disposed within the substrate 400. For example, the element isolation pattern 403 may be disposed within a second trench TR2 formed in the substrate 400. The second trench TR2 may be recessed from the first surface 400a of the substrate 400. The element isolation pattern 403 may be a shallow trench isolation (STI) film. The element isolation pattern 403 may define an active pattern. An upper surface of the element isolation pattern 403 may be disposed within the substrate 400. The width of the element isolation pattern 403 may gradually decrease from the first surface 400a to the second surface 400b of the substrate 400. The upper surface of the element isolation pattern 403 may be vertically spaced apart from the photoelectric conversion region 410.

Although not shown in the drawings, an amplification transistor and a selection transistor may also be disposed on the first surface 400a of the substrate 400. That is, a gate electrode of the amplifying transistor and a gate electrode of the selection transistor may be disposed on the first surface 400a of the substrate 400. Additionally, a reset transistor and a dual conversion transistor may be disposed on the first surface 400a of the substrate 400. The reset transistor may include a reset gate, and the dual conversion transistor may include a dual conversion gate.

A gate dielectric film GI may be disposed between each of a transmission gate TG, a selection gate, an amplification gate, the dual conversion gate, and the reset gate and the substrate 400. A gate spacer GS may be disposed on a sidewall of each gate electrode. For example, the gate spacer GS may include silicon nitride, silicon carbonitride, or silicon oxynitride.

However, in another embodiment, an opposite substrate (not shown) overlapping the substrate 400 may be further included, and one or more of the amplification transistor, the selection transistor, the reset transistor, or the dual conversion transistor may be disposed at the opposite substrate (not shown). In such embodiments, one or more of the amplification transistor, the selection transistor, the reset transistor, or the dual conversion transistor disposed at the opposing substrate may be connected to a transmission transistor TX disposed at the substrate 400 through a connection node (not shown).

The wiring region 20 may be disposed on the first surface 400a of the substrate 400.

The wiring region 20 may include a plurality of insulating layers IL1, IL2, and IL3, a plurality of wiring layers CL1 and CL2, and a via VIA.

The insulating layer may include the first insulating layer IL1, the second insulating layer IL2, and the third insulating layer IL3.

The first insulating layer IL1 may cover the first surface 400a of the substrate 400. The first insulating layer IL1 may cover a gate electrode TG. The second insulating layer IL2 may be disposed on the first insulating layer IL1. The third insulating layer IL3 may be disposed on the second insulating layer IL2.

The first to third insulating layers IL1, IL2, and IL3 may include a non-conductive material. For example, the first to third insulating layers IL1, IL2, and IL3 may include a silicon-based insulating material such as silicon oxide, silicon nitride, or silicon oxynitride.

The wiring region 20 may include a first wiring layer CL1 and a second wiring layer CL2. The first wiring layer CL1 may be disposed within the second insulating layer IL2. The second wiring layer CL2 may be disposed within the third insulating layer IL3.

A plurality of vias VIA may be disposed within the first insulating layer IL1, the second insulating layer IL2, and the third insulating layer IL3. Each via VIA may connect a floating diffusion region FD, the first wiring layer CL1, and/or the second wiring layer CL2 to each other.

The first wiring layer CL1, the second wiring layer CL2, and the via VIA may include a metal material. As an example, the first wiring layer CL1, the second wiring layer CL2, and the via VIA may include copper (Cu).

The light transmission layer 30 may be disposed on the second surface 400b of the substrate 400.

The light transmission layer 30 may include an insulating structure 329, a color filter 303, and the micro-lens 307. The light transmission layer 30 may collect and filter light incident from the outside to provide filtered light to the photoelectric conversion region 410.

The color filter 303 may be disposed above the second surface 400b of the substrate 400. The color filter 303 may be disposed over two pixels PXA and PXB that share the micro-lens 307. Each color filter 303 may include one primary color filter of a plurality of primary color filters. In other embodiments, the color filter 303 may be disposed over more than two pixels sharing a micro-lens.

The insulating structure 329 may be disposed between the second surface 400b of the substrate 400 and the color filter 303. The insulating structure 329 may prevent reflection of light so that light incident on the second surface 400b of the substrate 400 smoothly reaches the photoelectric conversion region 410. The insulating structure 329 may be referred to as an anti-reflection structure.

The insulating structure 329 may include a first fixed charge film 321, a second fixed charge film 323, and a planarization film 325 that are sequentially stacked on the second surface 400b of the substrate 400.

Each of the first fixed charge film 321, the second fixed charge film 323, and the planarization film 325 may include a different material.

The first fixed charge film 321 may include one of aluminum oxide, tantalum oxide, titanium oxide, and hafnium oxide. The second fixed charge film 323 may include another one of aluminum oxide, tantalum oxide, titanium oxide, and hafnium oxide. As an example, the first fixed charge film 321 may include aluminum oxide, the second fixed charge film 323 may include hafnium oxide, and the planarization film 325 may include silicon oxide.

Although not shown in the drawings, in another Embodiment, a silicon anti-reflection film (not shown) may be interposed between the second fixed charge film 323 and the planarization film 325. The anti-reflection film may include silicon nitride.

The micro-lens 307 may be disposed above the color filter 303. The micro-lens 307 may have a convex shape to collect light incident on the pixel PX. Each micro-lens 307 may vertically overlap the photoelectric conversion region 410. The shape of the lens may vary. Although one micro-lens 307 is shown in FIG. 4 in a shape overlapping photoelectric conversion regions 410 of the first pixel PXA and the second pixel PXB, the embodiment is not limited thereto, and one micro-lens 307 may overlap at least one photoelectric conversion region 410.

The light transmission layer 30 may further include a guide pattern 317 and a protective film 316.

The guide pattern 317 may overlap the first pixel isolation pattern 450A of the pixel isolation pattern 450 that surrounds the plurality of pixels PXA and PXB sharing the micro-lens 307.

The guide pattern 317 may be disposed on the insulating structure 329.

The guide pattern 317 may include a material with a lower refractive index than that of the color filter 303. When the guide pattern has a lower refractive index that the color filter 303, light that is passing through the color filter and that is obliquely incident to the guide pattern 317 may experience total internal reflection at the interface between the color filter 303 and the guide pattern 317 and be reflected back into the color filter 303.

The guide pattern 317 may include an organic material. For example, the guide pattern 317 may be a polymer layer including a silica nano particle. Because the guide pattern 317 has a low refractive index, the amount of light incident on the photoelectric conversion region 410 may be increased, and crosstalk between the pixels PX may be reduced. That is, the light reception efficiency may be increased in each photoelectric conversion region 410, and a signal noise ratio (SNR) characteristic may be improved.

According to another embodiment, the guide pattern 317 may include a metal. For example, the guide pattern 317 may include tungsten, but the embodiment is not limited thereto.

The protective film 316 may cover a surface of the guide pattern 317 with a uniform or substantially uniform thickness. For example, the protective film 316 may include at least one single layer or multiple layers among an aluminum oxide film and a silicon carbide oxide film. The protective film 316 may protect the color filter 303 and may have a moisture absorption function.

Referring to FIG. 5 along with FIG. 3 and FIG. 4, a central portion between the first pixel PXA and the second pixel PXB that are included in the first pixel group RG0 disposed at a central portion of the image sensor 100 along the first direction D1 and that share one micro-lens 307 may overlap or substantially overlap with a central portion of the micro-lens 307 along the first direction D1.

In addition, in the first pixel PXA and the second pixel PXB that are included in the first pixel group RG0 disposed at the central portion of the image sensor 100 and that share one micro-lens 307, the guide pattern 317 may overlap the first pixel isolation pattern 450A of the pixel isolation pattern 450 and may not overlap portions of the second pixel isolation pattern 450B of the pixel isolation pattern 450.

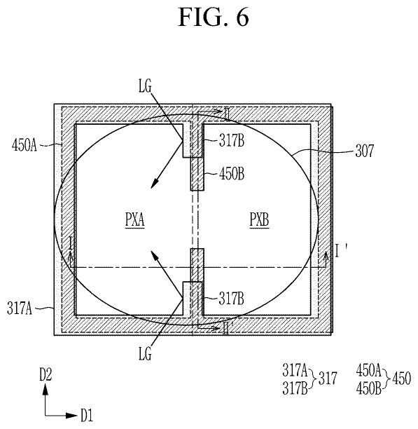

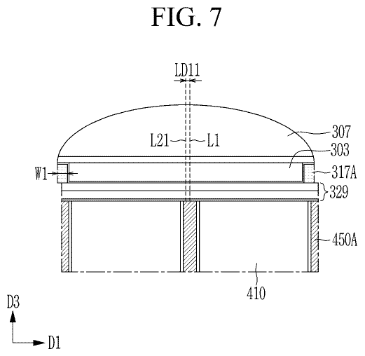

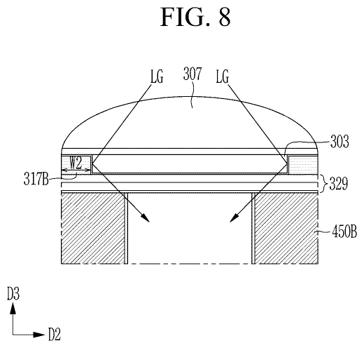

A plurality of pixels included in the second pixel group RG1A disposed at the left side with respect to the first pixel group RG0 will be described with reference to FIGS. 6 to 8. FIG. 6 is an enlarged view of a portion of FIG. 2, FIG. 7 is a cross-sectional view cut along a line I-I′ of FIG. 6, and FIG. 8 is a cross-sectional view showing a portion of FIG. 6 cut along a line II-II′. FIG. 7 and FIG. 8 show a portion corresponding to a portion indicated by “A” in FIG. 4.

Referring to FIG. 6 and FIG. 7, on a plane parallel to the first direction D1 and the second direction D2, a central portion of the micro-lens 307 shared by the plurality of pixels PXA and PXB included in the second pixel group RG1A may be misaligned such that the central portion of the micro-lens 307 does not overlap with the central portion between the plurality of pixels PXA and PXB along the third direction D3. The central portion of the micro-lens 307 may be shifted to the left with respect to the central portion between the plurality of pixels PXA and PXB. For example, the central portion of the lens may be shifted in the same direction in which the pixel group is disposed relative to the center pixel group.

An imaginary first line L1 passing through the central portion between the plurality of pixels PXA and PXB and parallel to the third direction D3 and an imaginary second line L21 passing through the central portion of the micro-lens 307 shared by the plurality of pixels PXA and PXB and parallel to the third direction D3 may not overlap each other and may be spaced apart by a first interval LD11 along the first direction D1.

Thus, the thickest portion of the micro-lens 307 and the central portion between the plurality of pixels PXA and PXB do not match (e.g., are not aligned in the third direction). Light entering at the oblique angle may be corrected in the image sensor so that it is directed at a center of each pixel.

In the first pixel PXA and the second pixel PXB that are included in the second pixel group RG1A disposed to be spaced apart from the central portion of the image sensor 100 to the left side and disposed at the left side with respect to the first pixel group RG0 and that share one micro-lens 307, the guide pattern 317 may include a first guide pattern 317A overlapping the first pixel isolation pattern 450A of the pixel isolation pattern 450 and a second guide pattern 317B extending toward a central portion between the first pixel PXA and the second pixel PXB along a direction parallel or substantially parallel to a direction in which the second pixel isolation pattern 450B extends from the first guide pattern 317A.

The first guide pattern 317A of the guide pattern 317 that overlaps the first pixel isolation pattern 450A of the pixel isolation pattern 450 may have a first width W1, and the second guide pattern 317B of the guide pattern 317 that extends from the first guide pattern 317A may have a second width W2.

The second width W2 of the second guide pattern 317B may be less than the width of the second pixel isolation pattern 450B of the pixel isolation pattern 450.

The second guide pattern 317B of the guide pattern 317 may reflect light LG that is incident obliquely toward the micro-lens 307 so that the light LG is incident on the photoelectric conversion region 410.

In addition, light that is incident obliquely toward the micro-lens 307 may normally be focused at a relatively high position from an upper surface of the substrate 400, but the second guide pattern 317B of the guide pattern 317 may reflect light LG that is obliquely incident so that the light LG is focused close to the upper surface of the substrate 400.

According to the embodiment, the guide pattern 317 of the image sensor 100 may include the second guide pattern 317B extending toward the central portion between the first pixel PXA and the second pixel PXB along the direction parallel or substantially parallel to the direction in which the second pixel isolation pattern 450B extends from the first guide pattern 317A. Thus, the second guide pattern 317B may reflect light that is obliquely incident toward the pixels spaced apart from the central portion of the image sensor 100 to the left side so that the light is incident on the photoelectric conversion region 410 and the light is focused close to the upper surface of the substrate 400. Therefore, a decrease in the efficiency of a pixel may be prevented by changing the optical path.

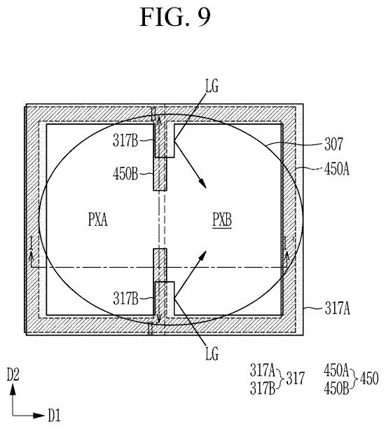

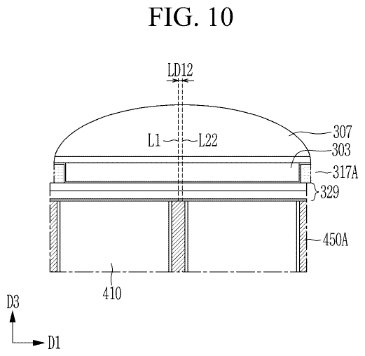

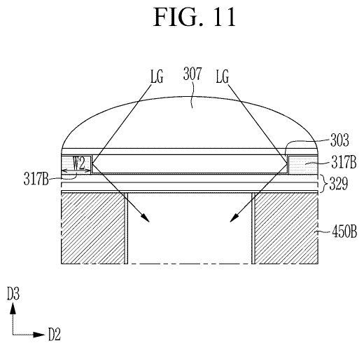

A plurality of pixels included in the third pixel group RG1B disposed at the right side with respect to the first pixel group RG0 will be described with reference to FIGS. 9 to 11. FIG. 9 is an enlarged view of a portion of FIG. 2, FIG. 10 is a cross-sectional view cut along a line I-I′ of FIG. 9, and FIG. 11 is a cross-sectional view showing a portion of FIG. 9 cut along a line II-II′. FIG. 10 and FIG. 11 show a portion corresponding to a portion indicated by “A” in FIG. 4.

Referring to FIG. 9 and FIG. 10, on a plane parallel to the first direction D1 and the second direction D2, a central portion of the micro-lens 307 shared by the plurality of pixels PXA and PXB included in the third pixel group RG1B may be misaligned such that the central portion of the micro-lens 307 does not overlap the central portion between the plurality of pixels PXA and PXB along the third direction D3. The central portion of the micro-lens 307 may be shifted to the right with respect to the central portion between the plurality of pixels PXA and PXB.

An imaginary first line L1 passing through the central portion between the plurality of pixels PXA and PXB and parallel to the third direction D3 and an imaginary second line L22 passing through the central portion of the micro-lens 307 shared by the plurality of pixels PXA and PXB and parallel to the third direction D3 may not overlap each other, and may be spaced apart by a first interval LD12 along the first direction D1.

Thus, the thickest portion of the micro-lens 307 and the central portion between the plurality of pixels PXA and PXB do not match (e.g., are not aligned in the third direction D3). Because at least some light enters at an oblique angle from the outside of the image sensor, the light entering at the oblique angle may be corrected in the image sensor so that it is disposed at a center of each pixel.

In the first pixel PXA and the second pixel PXB that are included in the third pixel group RG1B disposed to be spaced apart from the central portion of the image sensor 100 to the left side and disposed at the right side with respect to the first pixel group RG0 and that share one micro-lens 307, the guide pattern 317 may include a first guide pattern 317A overlapping the first pixel isolation pattern 450A of the pixel isolation pattern 450 and a second guide pattern 317B extending toward a central portion between the first pixel PXA and the second pixel PXB along a direction parallel or substantially parallel to a direction in which the second pixel isolation pattern 450B of the pixel isolation pattern 450 extends from the first guide pattern 317A.

The first guide pattern 317A of the guide pattern 317 that overlaps the first pixel isolation pattern 450A of the pixel isolation pattern 450 may have a first width W1, and the second guide pattern 317B of the guide pattern 317 that extends from the first guide pattern 317A may have a second width W2.

The second width W2 of the second guide pattern 317B may be less than the width of the second pixel isolation pattern 450B of the pixel isolation pattern 450.

The second guide pattern 317B of the guide pattern 317 may reflect light LG that is incident obliquely toward the micro-lens 307 so that the light LG is incident on the photoelectric conversion region 410.

In addition, light that is incident obliquely toward the micro-lens 307 may normally be focused at a relatively high position from an upper surface of the substrate 400, but the second guide pattern 317B of the guide pattern 317 may reflect light LG that is obliquely incident so that the light LG is focused close to the upper surface of the substrate 400.

According to the embodiment, the guide pattern 317 of the image sensor 100 may include the second guide pattern 317B. Thus, the second guide pattern 317B may help reflect light that is obliquely incident toward the pixels spaced apart from the central portion of the image sensor 100 to the left side so that the light is incident on the photoelectric conversion region 410 and the light is focused close to the upper surface of the substrate 400. Therefore, a decrease in the efficiency of a pixel may be prevented by changing the optical path.

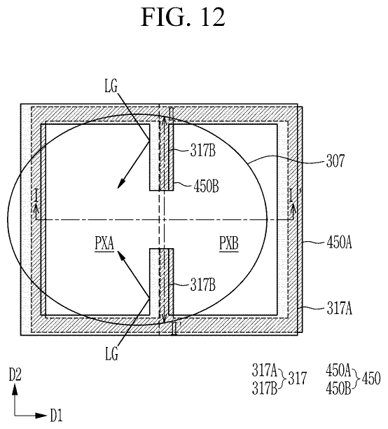

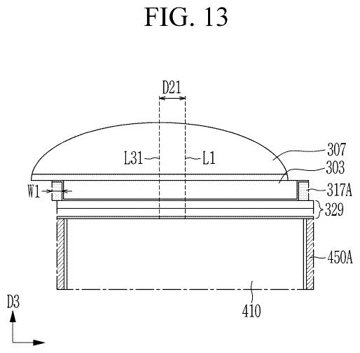

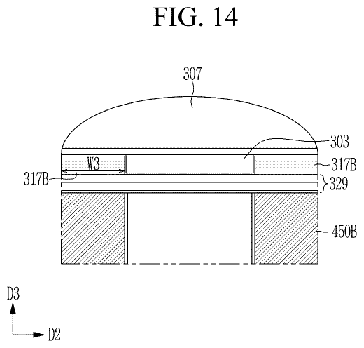

A plurality of pixels included in the fourth pixel group RG2A disposed at the left side of the second pixel group RG1A and adjacent to an edge portion of the image sensor 100 will be described with reference to FIGS. 12 to 14. FIG. 12 is an enlarged view of a portion of FIG. 2, FIG. 13 is a cross-sectional view cut along a line I-I′ of FIG. 12, and FIG. 14 is a cross-sectional view showing a portion of FIG. 12 cut along a line II-II′. FIG. 13 and FIG. 14 show a portion corresponding to a portion indicated by “A” in FIG. 4.

Referring to FIG. 12 and FIG. 13, on a plane parallel to the first direction D1 and the second direction D2, a central portion of the micro-lens 307 shared by the plurality of pixels PXA and PXB included in the fourth pixel group RG2A may be misaligned such that the central portion of the micro-lens 307 does not overlap the central portion between the plurality of pixels PXA and PXB along the third direction D3. The central portion of the micro-lens 307 may be shifted to the left with respect to the central portion between the plurality of pixels PXA and PXB.

An imaginary first line L1 passing through the central portion between the plurality of pixels PXA and PXB and parallel to the third direction D3 and an imaginary second line L31 passing through the central portion of the micro-lens 307 shared by the plurality of pixels PXA and PXB and parallel to the third direction D3 may not overlap each other, and may be spaced apart by a second interval LD21 along the first direction D1. The second interval LD21 may be larger than the first interval LD11.

Thus, the thickest portion of the micro-lens 307 and the central portion between the plurality of pixels PXA and PXB do not match (e.g., are not aligned in the third direction D3). Light entering at the oblique angle may be corrected in the image sensor so that light entering at the oblique angle is directed at a center of each pixel.

In the first pixel PXA and the second pixel PXB that are included in the fourth pixel group RG2A disposed to be spaced apart from the central portion of the image sensor 100 to the left side and disposed at the left side with respect to the first pixel group RG0 and that share one micro-lens 307, the guide pattern 317 may include a first guide pattern 317A overlapping the first pixel isolation pattern 450A of the pixel isolation pattern 450 and a second guide pattern 317B extending toward a central portion between the first pixel PXA and the second pixel PXB along a direction parallel or substantially parallel to a direction in which the second pixel isolation pattern 450B extends from the first guide pattern 317A.

The first guide pattern 317A of the guide pattern 317 that overlaps the first pixel isolation pattern 450A of the pixel isolation pattern 450 may have a first width W1, and the second guide pattern 317B of the guide pattern 317 may have a third width W3. The third width W3 may be greater than the second width W2.

The third width W3 of the second guide pattern 317B may be approximately the same as the width of the second pixel isolation pattern 450B of the pixel isolation pattern 450.

The fourth pixel group RG2A may be disposed closer to an edge portion of the image sensor 100 than the second pixel group RG1A, and the light LG incident on the fourth pixel group RG2A may be obliquely incident more than the light incident on the second pixel group RG1A.

Because the second guide pattern 317B of the guide pattern 317 of the fourth pixel group RG2A has a wider width than that of the second guide pattern 317B of the guide pattern 317 of the second pixel group RG1A, the second guide pattern 317B of the guide pattern 317 of the fourth pixel group RG2A may reflect more light LG that is incident obliquely toward the micro-lens 307 so that the light LG is incident on the photoelectric conversion region 410.

Light that is incident obliquely toward the micro-lens 307 may normally be focused at a relatively high position from an upper surface of the substrate 400. However, because the second guide pattern 317B of the guide pattern 317 of the fourth pixel group RG2A has a wider width than that of the second guide pattern 317B of the guide pattern 317 of the second pixel group RG1A, the second guide pattern 317B of the guide pattern 317 of the fourth pixel group RG2A may reflect more light LG that is incident obliquely toward the micro-lens 307 and may reflect light LG that is obliquely incident so that the light LG is focused close to the upper surface of the substrate 400.

According to the embodiment, the guide pattern 317 of the image sensor 100 may include the second guide pattern 317B. Thus, the second guide pattern 317B may reflect light that is obliquely incident toward the pixels spaced apart from the central portion of the image sensor 100 to the left side so that the light is incident on the photoelectric conversion region 410 and the light is focused close to the upper surface of the substrate 400. Therefore, a decrease in the efficiency of the pixel may be prevented by changing the optical path.

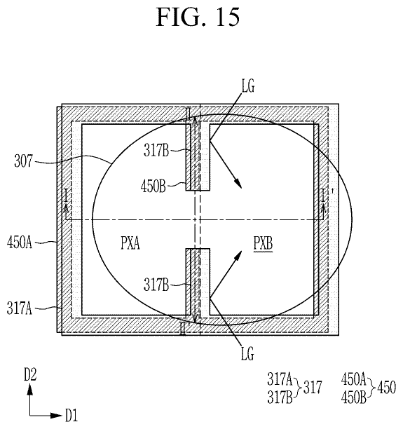

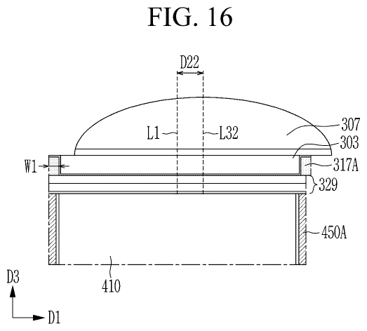

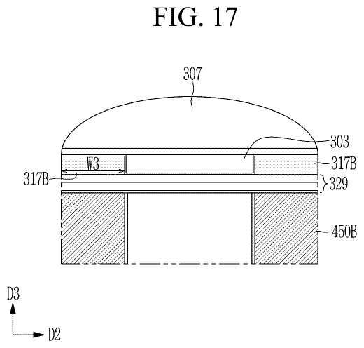

A plurality of pixels included in the fifth pixel group RG2B disposed at the right side of the third pixel group RG1B and adjacent to an edge portion of the image sensor 100 will be described with reference to FIGS. 15 to 17. FIG. 15 is an enlarged view of a portion of FIG. 2, FIG. 16 is a cross-sectional view cut along a line I-I′ of FIG. 15, and FIG. 17 is a cross-sectional view showing a portion of FIG. 15 cut along a line II-II′. FIG. 16 and FIG. 17 show a portion corresponding to a portion indicated by “A” in FIG. 4.

Referring to FIG. 15 and FIG. 16, on a plane parallel to the first direction D1 and the second direction D2, a central portion of the micro-lens 307 shared by the plurality of pixels PXA and PXB included in the fifth pixel group RG2B may be misaligned such that the central portion of the micro-lens 307 does not overlap without the central portion between the plurality of pixels PXA and PXB along the third direction D3. The central portion of the micro-lens 307 may be shifted to the right with respect to the central portion between the plurality of pixels PXA and PXB.

An imaginary first line L1 passing through the central portion between the plurality of pixels PXA and PXB and parallel to the third direction D3 and an imaginary second line L32 passing through the central portion of the micro-lens 307 shared by the plurality of pixels PXA and PXB and parallel to the third direction D3 may not overlap each other, and may be spaced apart by a second interval LD22 along the first direction D1. The second interval LD22 may be larger than the first interval LD12.

Thus, the thickest portion of the micro-lens 307 and the central portion between the plurality of pixels PXA and PXB do not match (e.g., are not aligned in the third direction D3). Light entering at the oblique angle may be corrected in the image sensor so that light entering at the oblique angle is directed at a center of each pixel.

In the first pixel PXA and the second pixel PXB that are included in the fifth pixel group RG2B disposed to be spaced apart from the central portion of the image sensor 100 to the left side and disposed at the right side with respect to the first pixel group RG0 and that share one micro-lens 307, the guide pattern 317 may include a first guide pattern 317A overlapping the first pixel isolation pattern 450A of the pixel isolation pattern 450 and a second guide pattern 317B extending toward a central portion between the first pixel PXA and the second pixel PXB along a direction parallel or substantially parallel to a direction in which the second pixel isolation pattern 450B of the pixel isolation pattern 450 extends from the first guide pattern 317A.

The first guide pattern 317A of the guide pattern 317 that overlaps the first pixel isolation pattern 450A of the pixel isolation pattern 450 may have a first width W1, and the second guide pattern 317B of the guide pattern 317 that extends from the first guide pattern 317A may have a third width W3. The third width W3 may be greater than the second width W2.

The third width W3 of the second guide pattern 317B that overlaps the second pixel isolation pattern 450B of the pixel isolation pattern 450 may be the same as or substantially the same as a width of the second pixel isolation pattern 450B of the pixel isolation pattern 450.

The fifth pixel group RG2B may be disposed closer to an edge portion of the image sensor 100 than the third pixel group RG1B and light incident on the fifth pixel group RG2B may be more obliquely incident than light incident on the third pixel group RG1B.

Because the second guide pattern 317B of the guide pattern 317 of the fifth pixel group RG2B has a wider width than that of the second guide pattern 317B of the guide pattern 317 of the third pixel group RG1B, the second guide pattern 317B of the guide pattern 317 of the fifth pixel group RG2B may reflect light LG that is incident obliquely toward the micro-lens 307 so that the light LG is incident on the photoelectric conversion region 410.

Light that is incident obliquely toward the micro-lens 307 may normally be focused at a relatively high position from an upper surface of the substrate 400. However, because the second guide pattern 317B of the guide pattern 317 of the fifth pixel group RG2B has a wider width than that of the second guide pattern 317B of the guide pattern 317 of the third pixel group RG1B, the second guide pattern 317B of the guide pattern 317 of the fifth pixel group RG2B may reflect more light LG that is incident obliquely toward the micro-lens 307, and may reflect light LG that is obliquely incident so that the light LG is focused close to the upper surface of the substrate 400.

According to the embodiment, the guide pattern 317 of the image sensor 100 may include the second guide pattern 317B. Thus, the second guide pattern 317B may reflect light LG that is obliquely incident toward the pixels spaced apart from the central portion of the image sensor 100 to the left side so that the light is incident on the photoelectric conversion region 410 and the light is focused close to the upper surface of the substrate 400. Therefore, a decrease in the efficiency of the pixel PX may be prevented by changing the optical path.

According to the embodiment, the image sensor 100 may include the second guide pattern extending along a center of the plurality of pixels sharing the micro-lens, and a width of the second guide pattern may be adjusted differently depending on a region of the image sensor 100. The width of the second guide pattern may be adjusted to correct a difference in intensity and a difference in a focal position of light incident on the photoelectric conversion region 410 that may occur according to a difference in an incident angle of light incident according to the position of the image sensor 100.

According to the embodiment, the difference in the incident angle of light incident according to the position of the image sensor 100 may be corrected using the second guide pattern, so that a decrease in the efficiency of the pixel PX is prevented by changing the optical path.

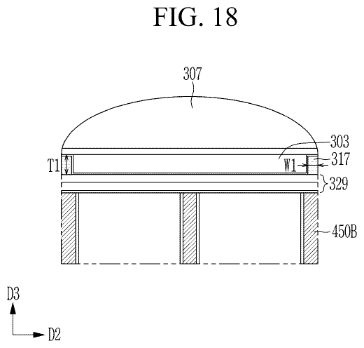

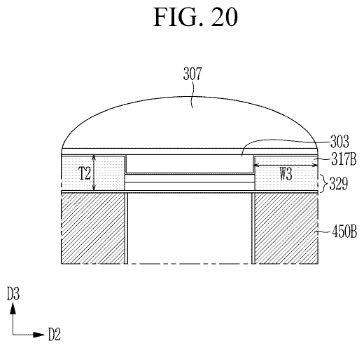

An image sensor according to another embodiment will be described with reference to FIGS. 18 to 20. FIG. 18 is a cross-sectional view cut along the line I-I′ of each of FIGS. 3, 6, 9, 12, and 15, FIG. 19 is a cross-sectional view cut along the line II-II′ of each of FIG. 6 and FIG. 9, and FIG. 20 is a cross-sectional view cut along the line II-II′ of each of FIG. 12 and FIG. 15. FIGS. 18 to 20 show a portion corresponding to a portion indicated by “A” in FIG. 4.

Referring to FIG. 18, a central portion between the first pixel PXA and the second pixel PXB that are included in the first pixel group RG0 disposed at a central portion of the image sensor 100 along the first direction D1 and that share one micro-lens 307 may overlap or substantially overlap with a central portion in the first direction of the micro-lens 307 in the third direction D3.

In addition, in the first pixel PXA and the second pixel PXB that are included in the first pixel group RG0 disposed at the central portion of the image sensor 100 and that share one micro-lens 307, the guide pattern 317 may overlap the first pixel isolation pattern 450A of the pixel isolation pattern 450 in the third direction and may not overlap portions of the second pixel isolation pattern 450B of the pixel isolation pattern 450.

The guide pattern 317 that overlaps the first pixel isolation pattern 450A of the pixel isolation pattern 450 in the third direction may have a first width W1. Additionally, the guide pattern 317 that overlaps the first pixel isolation pattern 450A of the pixel isolation pattern 450 in the third direction D3 may have a first thickness T1.

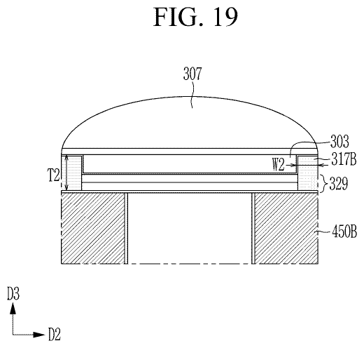

Referring to FIG. 19, the first guide pattern 317A of the guide pattern 317 of each of the second pixel group RG1A disposed at the left side with respect to the first pixel group RG0 along the first direction D1 and the third pixel group RG1B disposed at the right side with respect to the first pixel group RG0 along the first direction D1 may have a first width W1, and the second guide pattern 317B extending from the first guide pattern 317A of the guide patterns 317 may have a second width W2. The second width W2 may be larger than the first width W1.

Additionally, the second guide pattern 317B of the guide pattern 317 may have a second thickness T2 and may extend toward the insulating structure 329. The second thickness T2 may be larger than the first thickness T1.

The second guide pattern 317B may help reflect light that is obliquely incident toward the micro-lens 307 so that the light is incident on the photoelectric conversion region 410 and the light is focused close to an upper surface of the substrate 400. Therefore, a decrease in the efficiency of the pixel may be prevented by changing the optical path.

Referring to FIG. 20, the first guide pattern 317A of the guide pattern 317 overlapping the first pixel isolation pattern 450A of the pixel isolation pattern 450 of each of the fourth pixel group RG2A disposed at the left side of the second pixel group RG1A and adjacent to an edge portion of the image sensor 100 along the first direction D1 and the fifth pixel group RG2B disposed at the right side of the third pixel group RG1B and adjacent to the edge portion of the image sensor 100 along the first direction D1 may have a first width W1, and the second guide pattern 317B of the guide pattern 317 that extends from the first guide pattern 317A may have a third width W3. The third width W3 may be larger than the first width W1 and the second width W2.

Additionally, the second guide pattern 317B of the guide pattern 317 may have a second thickness T2 and may extend toward the insulating structure 329. The second thickness T2 may be larger than the first thickness T1.

The second guide pattern 317B may reflect light that is obliquely incident toward the micro-lens 307 so that the light is incident on the photoelectric conversion region 410 and the light is focused close to an upper surface of the substrate 400. Therefore, a decrease in the efficiency of the pixel may be prevented by changing the optical path.

According to the embodiment, the image sensor 100 may include the second guide pattern extending toward a central portion of the plurality of pixels sharing the micro-lens, and a width and a thickness of the second guide pattern may be differently adjusted depending on a region of the image sensor 100 so that the second guide pattern corrects a difference in intensity and a difference in a focal position of light incident on the photoelectric conversion region 410 that may occur according to a difference in an incident angle of light incident according to a position of the image sensor 100.

According to the embodiment, the difference in the incident angle of light incident according to the position of the image sensor 100 may be corrected using the second guide pattern, so that a decrease in the efficiency of the pixel may be prevented by changing the optical path.

Many features of the image sensor according to the embodiment described above are all applicable to the image sensor according to the present embodiment.

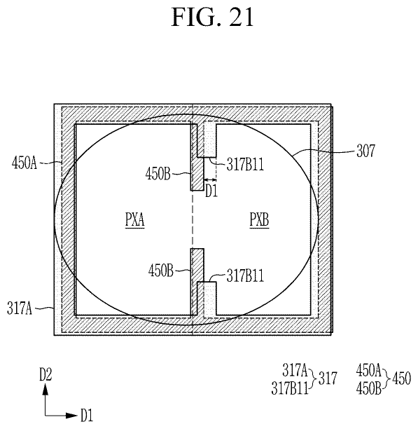

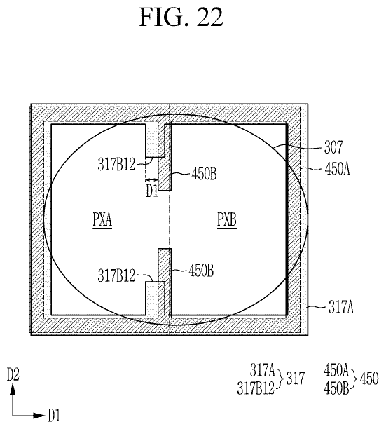

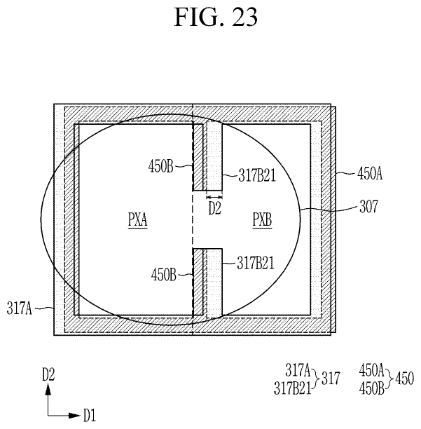

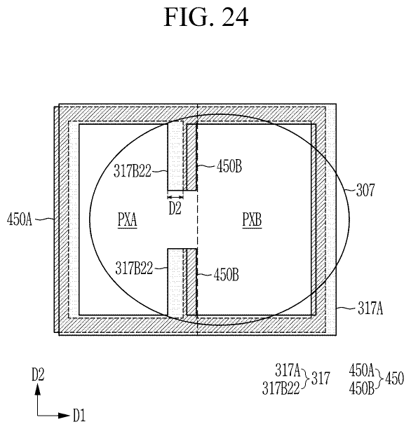

An image sensor according to another embodiment will be described with reference to FIGS. 21 to 24 together with FIGS. 3 to 5. FIGS. 21 to 24 are enlarged views of a portion of FIG. 2. FIG. 21 shows a plurality of pixels included in the second pixel group RG1A, FIG. 22 shows a plurality of pixels included in the third pixel group RG1B, FIG. 23 shows a plurality of pixels included in the fourth pixel group RG2A, and FIG. 24 shows a plurality of pixels included in the fifth pixel group RG2B.

Referring to FIG. 21, on a plane parallel to the first direction D1 and the second direction D2, a central portion of the micro-lens 307 shared by the plurality of pixels PXA and PXB included in the second pixel group RG1A may be misaligned such that the central portion of the micro-lens 307 does not overlap with the central portion between the plurality of pixels PXA and PXB. The central portion of the micro-lens 307 may be shifted to the left with respect to the central portion between the plurality of pixels PXA and PXB.

Although not shown in the drawings, as shown in FIGS. 6 to 8, the central portion of the micro-lens 307 may be spaced apart from the central portion between the plurality of pixels PXA and PXB by the first interval LD11 along the first direction D1.

In the first pixel PXA and the second pixel PXB that are included in the second pixel group RG1A and share one micro-lens 307, the guide pattern 317 may include the first guide pattern 317A of the guide pattern 317 overlapping the first pixel isolation pattern 450A of the pixel isolation pattern 450 and a second guide pattern 317B11 extending from the first guide pattern 317A toward a central portion between the first pixel PXA and the second pixel PXB along the second direction D2 to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317B11 of the guide pattern 317 may have a second width W2.

The second guide pattern 317B11 may be disposed to be shifted to the right of the second pixel isolation pattern 450B of the pixel isolation pattern 450 along the first direction D1. A portion of the second guide pattern 317B11 may not overlap the second pixel isolation pattern 450B, and the portion of the second guide pattern 317B11 that does not overlap the second pixel isolation pattern 450B may have the first width W1 along the first direction D1.

The second guide pattern 317B11 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B11 of the guide pattern 317 may reflect light that is obliquely incident so that the light is focused close to the upper surface of the substrate 400.

Referring to FIG. 22, on a plane parallel to the first direction D1 and the second direction D2, a central portion of the micro-lens 307 shared by the plurality of pixels PXA and PXB included in the third pixel group RG1B may be misaligned such that the central portion of the micro-lens 307 does not overlap with the central portion between the plurality of pixels PXA and PXB. The central portion of the micro-lens 307 may be shifted to the right with respect to the central portion between the plurality of pixels PXA and PXB.

Although not shown in the drawings, as shown in FIGS. 9 to 11, the central portion of the micro-lens 307 may be spaced apart from the central portion between the plurality of pixels PXA and PXB by the first interval LD12 along the first direction D1.

In the first pixel PXA and the second pixel PXB that are included in the third pixel group RG1B and share one micro-lens 307, the guide pattern 317 may include the first guide pattern 317A of the guide pattern 317 overlapping the first pixel isolation pattern 450A of the pixel isolation pattern 450 and a second guide pattern 317B12 extending from the first guide pattern 317A toward a central portion between the first pixel PXA and the second pixel PXB along the second direction D2 to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317B12 of the guide pattern 317 may have a second width W2.

The second guide pattern 317B12 may be disposed to be shifted to the left of the second pixel isolation pattern 450B of the pixel isolation pattern 450 along the first direction D1. A portion of the second guide pattern 317B12 may not overlap the second pixel isolation pattern 450B, and the portion of the second guide pattern 317B12 that does not overlap the second pixel isolation pattern 450B may have the first width W1 along the first direction D1.

The second guide pattern 317B12 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B12 of the guide pattern 317 may reflect light that is obliquely incident so that the light is focused close to the upper surface of the substrate 400.

Referring to FIG. 23, on a plane parallel to the first direction D1 and the second direction D2, a central portion of the micro-lens 307 shared by the plurality of pixels PXA and PXB included in the fourth pixel group RG2A may be misaligned such that the central portion of the micro-lens 307 does not overlap with the central portion between the plurality of pixels PXA and PXB. The central portion of the micro-lens 307 may be shifted to the left with respect to the central portion between the plurality of pixels PXA and PXB.

Although not shown in the drawings, as shown in FIGS. 12 to 14, the central portion of the micro-lens 307 may be spaced apart from the central portion between the plurality of pixels PXA and PXB by the second interval LD21 along the first direction D1.

In the first pixel PXA and the second pixel PXB that are included in the second pixel group RG1A and share one micro-lens 307, the guide pattern 317 may include the first guide pattern 317A of the guide pattern 317 overlapping the first pixel isolation pattern 450A of the pixel isolation pattern 450 and a second guide pattern 317B21 extending from the first guide pattern 317A toward a central portion between the first pixel PXA and the second pixel PXB along the second direction D2 to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317B21 of the guide pattern 317 may have a third width W3. The third width W3 may be larger than the second width W2.

The second guide pattern 317B21 may be disposed to be shifted to the right of the second pixel isolation pattern 450B of the pixel isolation pattern 450 along the first direction D1. A portion of the second guide pattern 317B21 may not overlap the second pixel isolation pattern 450B, and the portion of the second guide pattern 317B21 that does not overlap the second pixel isolation pattern 450B may have the second width W2 along the first direction D1. The second width W2 may be larger than the first width W1.

The second guide pattern 317B21 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B21 of the guide pattern 317 may reflect light that is obliquely incident so that the light is focused close to the upper surface of the substrate 400.

Referring to FIG. 24, on a plane parallel to the first direction D1 and the second direction D2, a central portion of the micro-lens 307 shared by the plurality of pixels PXA and PXB included in the fifth pixel group RG2B may be misaligned such that the central portion of the micro-lens 307 does not overlap with the central portion between the plurality of pixels PXA and PXB. The central portion of the micro-lens 307 may be shifted to the right with respect to the central portion between the plurality of pixels PXA and PXB.

Although not shown in the drawings, as shown in FIGS. 15 to 17, the central portion of the micro-lens 307 may be spaced apart from the central portion between the plurality of pixels PXA and PXB by the second interval LD22 along the first direction D1.

In the first pixel PXA and the second pixel PXB that are included in the fifth pixel group RG2B and share one micro-lens 307, the guide pattern 317 may include the first guide pattern 317A of the guide pattern 317 overlapping the first pixel isolation pattern 450A of the pixel isolation pattern 450 and a second guide pattern 317B22 extending from the first guide pattern 317A toward a central portion between the first pixel PXA and the second pixel PXB along the second direction D2 to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317B22 of the guide pattern 317 may have a third width W3. The third width W3 may be larger than the second width W2.

The second guide pattern 317B22 may be disposed to be shifted to the left of the second pixel isolation pattern 450B of the pixel isolation pattern 450 along the first direction D1. A portion of the second guide pattern 317B22 may not overlap the second pixel isolation pattern 450B, and the portion of the second guide pattern 317B22 that does not overlap the second pixel isolation pattern 450B may have the second width W2 along the first direction D1. The second width W2 may be larger than the first width W1.

The second guide pattern 317B22 of the guide pattern 317 may reflect light that is obliquely incident toward the micro-lens 307 so that the light is incident on the photoelectric conversion region 410.

In addition, light incident that is obliquely incident toward the micro-lens 307 may normally be focused at a relatively high position from an upper surface of the substrate 400, but the second guide pattern 317B22 of the guide pattern 317 may reflect light that is obliquely incident so that the light is focused close to the upper surface of the substrate 400.

According to the present embodiment, the second guide pattern 317B may reflect light that is obliquely incident toward the micro-lens 307 so that the light is incident on the photoelectric conversion region 410 and the light is focused close to the upper surface of the substrate 400. Therefore, a decrease in the efficiency of the pixel PX may be prevented by changing the optical path.

According to the embodiment, the image sensor 100 may include the second guide pattern extending toward a central portion of the plurality of pixels sharing the micro-lens, and a width and a position of the second guide pattern may be differently adjusted depending on a region of the image sensor 100 so that the second guide pattern corrects a difference in intensity and a difference in a focal position of light incident on the photoelectric conversion region 410 that may occur according to a difference in an incident angle of light incident according to a position of the image sensor 100.

According to the embodiment, the difference in the incident angle of light incident according to the position of the image sensor 100 may be corrected using the second guide pattern, so that the decrease in the efficiency of the pixel PX is prevented by changing the optical path.

Many features of the image sensors according to the embodiments described above are all applicable to the image sensor according to the present embodiment.

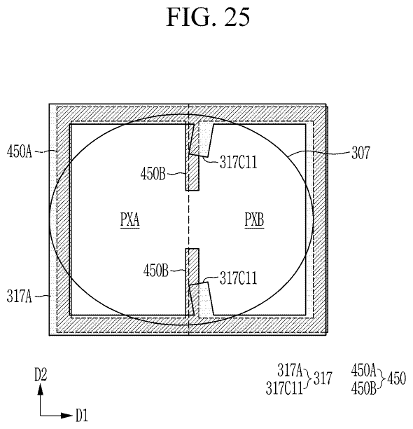

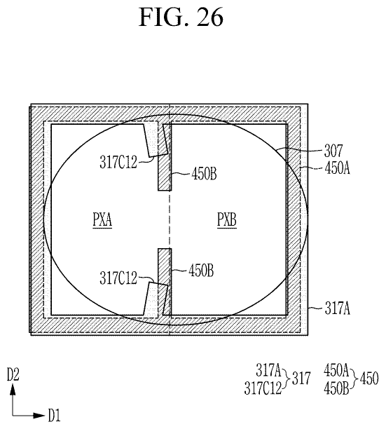

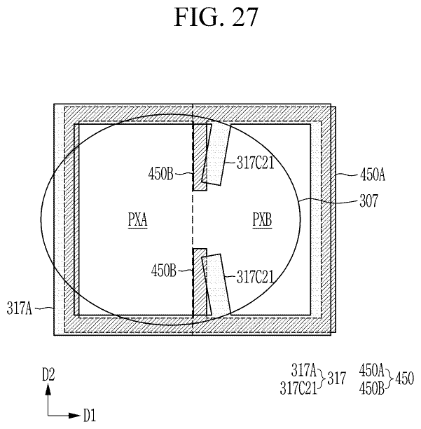

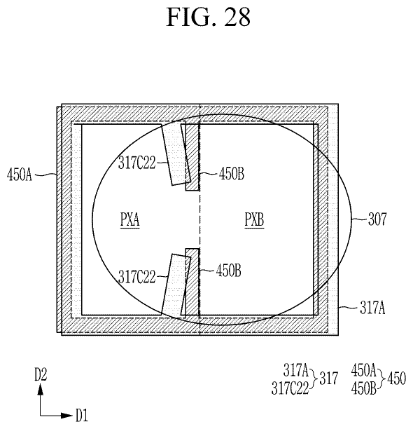

An image sensor according to another embodiment will be described with reference to FIGS. 25 to 28 together with FIGS. 3 to 5. FIGS. 25 to 28 are enlarged views of a portion of FIG. 2. FIG. 25 shows a plurality of pixels included in the second pixel group RG1A, FIG. 26 shows a plurality of pixels included in the third pixel group RG1B, FIG. 27 shows a plurality of pixels included in the fourth pixel group RG2A, and FIG. 28 shows a plurality of pixels included in the fifth pixel group RG2B.

Referring to FIG. 25, on a plane parallel to the first direction D1 and the second direction D2, a central portion of the micro-lens 307 shared by the plurality of pixels PXA and PXB included in the second pixel group RG1A may be misaligned such that the central portion of the micro-lens 307 does not overlap with the central portion between the plurality of pixels PXA and PXB. The central portion of the micro-lens 307 may be shifted to the left with respect to the central portion between the plurality of pixels PXA and PXB.

Although not shown in the drawings, as shown in FIGS. 6 to 8, the central portion of the micro-lens 307 may be spaced apart from the central portion between the plurality of pixels PXA and PXB by the first interval LD11 along the first direction D1.

In the first pixel PXA and the second pixel PXB that are included in the second pixel group RG1A and share one micro-lens 307, the guide pattern 317 may include the first guide pattern 317A of the guide pattern 317 overlapping the first pixel isolation pattern 450A of the pixel isolation pattern 450 and a second guide pattern 317C11 extending from the first guide pattern 317A toward a central portion between the first pixel PXA and the second pixel PXB to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317C11 of the guide pattern 317 may have a second width W2. The second guide pattern 317C11 may be disposed to be shifted to the right of the second pixel isolation pattern 450B of the pixel isolation pattern 450 along the first direction D1, and the second guide pattern 317C11 may extend obliquely to the left so as to further overlap the second pixel isolation pattern 450B as a distance between the second guide pattern 317C11 and the first guide pattern 317A increases.

The second guide pattern 317C11 of the guide pattern 317 that overlaps the second pixel isolation pattern 450B of the pixel isolation pattern 450 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317C11 of the guide pattern 317 may reflect light that is obliquely incident so that the light is focused close to the upper surface of the substrate 400.

Referring to FIG. 26, on a plane parallel to the first direction D1 and the second direction D2, a central portion of the micro-lens 307 shared by the plurality of pixels PXA and PXB included in the third pixel group RG1B may be misaligned such that the central portion of the micro-lens 307 does not overlap with the central portion between the plurality of pixels PXA and PXB. The central portion of the micro-lens 307 may be shifted to the right with respect to the central portion between the plurality of pixels PXA and PXB.

Although not shown in the drawings, as shown in FIGS. 9 to 11, the central portion of the micro-lens 307 may be spaced apart from the central portion between the plurality of pixels PXA and PXB by the first interval LD12 along the first direction D1.

In the first pixel PXA and the second pixel PXB that are included in the third pixel group RG1B and share one micro-lens 307, the guide pattern 317 may include the first guide pattern 317A of the guide pattern 317 overlapping the first pixel isolation pattern 450A of the pixel isolation pattern 450 and a second guide pattern 317C12 extending from the first guide pattern 317A toward a central portion between the first pixel PXA and the second pixel PXB to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317C12 of the guide pattern 317 may have a second width W2. The second guide pattern 317C12 may be disposed to be shifted to the left of the second pixel isolation pattern 450B of the pixel isolation pattern 450 along the first direction D1, and the second guide pattern 317C12 may obliquely extend so as to further overlap the second pixel isolation pattern 450B as a distance between the second guide pattern 317C12 and the first guide pattern 317A increases.

The second guide pattern 317C12 of the guide pattern 317 that overlaps the second pixel isolation pattern 450B of the pixel isolation pattern 450 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317C12 of the guide pattern 317 may reflect light that is obliquely incident so that the light is focused close to the upper surface of the substrate 400.

Referring to FIG. 27, on a plane parallel to the first direction D1 and the second direction D2, a central portion of the micro-lens 307 shared by the plurality of pixels PXA and PXB included in the fourth pixel group RG2A may be misaligned such that the central portion of the micro-lens 307 does not overlap with the central portion between the plurality of pixels PXA and PXB. The central portion of the micro-lens 307 may be shifted to the left with respect to the central portion between the plurality of pixels PXA and PXB.

Although not shown in the drawings, as shown in FIGS. 12 to 14, the central portion of the micro-lens 307 may be spaced apart from the central portion between the plurality of pixels PXA and PXB by the second interval LD21 along the first direction D1.

In the first pixel PXA and the second pixel PXB that are included in the second pixel group RG1A and share one micro-lens 307, the guide pattern 317 may include the first guide pattern 317A of the guide pattern 317 overlapping the first pixel isolation pattern 450A of the pixel isolation pattern 450 and a second guide pattern 317C21 extending from the first guide pattern 317A toward a central portion between the first pixel PXA and the second pixel PXB to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317C21 of the guide pattern 317 may have a second width W2. The second guide pattern 317C21 may be disposed to be shifted to the right of the second pixel isolation pattern 450B of the pixel isolation pattern 450 along the first direction D1, and the second guide pattern 317C21 may obliquely extend so as to further overlap the second pixel isolation pattern 450B as a distance between the second guide pattern 317C21 and the first guide pattern 317A increases.

The second guide pattern 317C21 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317C21 of the guide pattern 317 may reflect light that is obliquely incident so that the light is focused close to the upper surface of the substrate 400.

Referring to FIG. 28, on a plane parallel to the first direction D1 and the second direction D2, a central portion of the micro-lens 307 shared by the plurality of pixels PXA and PXB included in the fifth pixel group RG2B may be misaligned such that the central portion of the micro-lens 307 does not overlap with the central portion between the plurality of pixels PXA and PXB. The central portion of the micro-lens 307 may be shifted to the right with respect to the central portion between the plurality of pixels PXA and PXB.

Although not shown in the drawings, as shown in FIGS. 15 to 17, the central portion of the micro-lens 307 may be spaced apart from the central portion between the plurality of pixels PXA and PXB by the second interval LD22 along the first direction D1.

In the first pixel PXA and the second pixel PXB that are included in the fifth pixel group RG2B and share one micro-lens 307, the guide pattern 317 may include the first guide pattern 317A of the guide pattern 317 overlapping the first pixel isolation pattern 450A of the pixel isolation pattern 450 and a second guide pattern 317C22 extending from the first guide pattern 317A toward a central portion between the first pixel PXA and the second pixel PXB to overlap at least a portion of the second pixel isolation pattern 450B of the pixel isolation pattern 450.

The first guide pattern 317A of the guide pattern 317 that overlaps the first pixel isolation pattern 450A of the pixel isolation pattern 450 may have a first width W1, and the second guide pattern 317C22 of the guide pattern 317 that extends from the first guide pattern 317A may have a third width W3. The second guide pattern 317C22 may be disposed to be shifted to the left of the second pixel isolation pattern 450B of the pixel isolation pattern 450 along the first direction D1, and the second guide pattern 317C22 may obliquely extend so as to further overlap the second pixel isolation pattern 450B as a distance between the second guide pattern 317C22 and the first guide pattern 317A increases. The third width W3 may be larger than the second width W2.

The second guide pattern 317C22 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317C22 of the guide pattern 317 may reflect light that is obliquely incident so that the light is focused close to the upper surface of the substrate 400.

According to the present embodiment, the second guide pattern 317C22 may help refract light that is obliquely incident toward the micro-lens 307 so that the light is incident on the photoelectric conversion region 410 and the light is focused close to the upper surface of the substrate 400. Therefore, a decrease in the efficiency of the pixel PX may be prevented by changing the optical path.

According to the embodiment, the image sensor 100 may include the second guide pattern extending toward a central portion of the plurality of pixels sharing the micro-lens, and a width and a position of the second guide pattern may be differently adjusted depending on a region of the image sensor 100 so that the second guide pattern corrects a difference in intensity and a difference in a focal position of light that is incident on the photoelectric conversion region 410 that may occur according to a difference in an incident angle of light that is incident according to a position of the image sensor 100.

According to the embodiment, the difference in the incident angle of light incident according to the position of the image sensor 100 may be corrected using the second guide pattern, so that the decrease in the efficiency of the pixel PX is prevented by changing the optical path.

Many features of the image sensors according to the embodiments described above are all applicable to the image sensor according to the present embodiment.

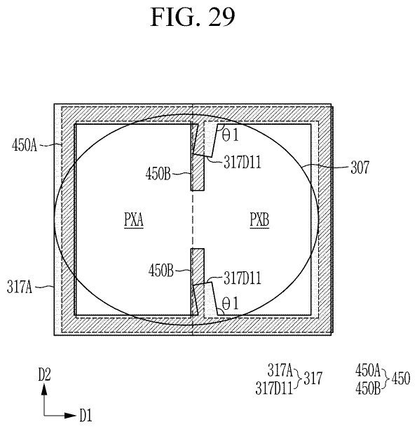

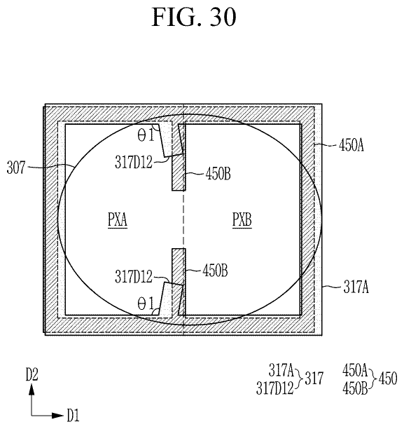

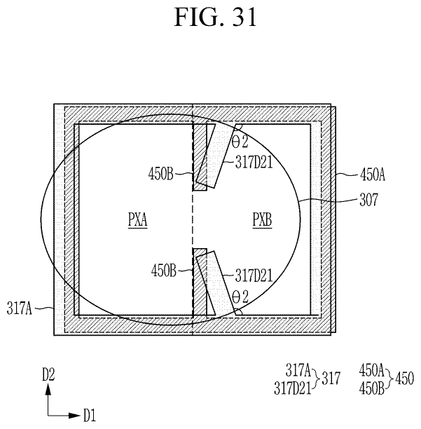

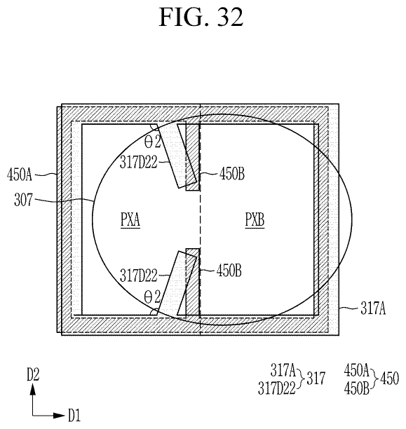

An image sensor according to another embodiment will be described with reference to FIGS. 29 to 32 together with FIGS. 3 to 5. FIGS. 29 to 32 are enlarged views of a portion of FIG. 2. FIG. 29 shows a plurality of pixels included in the second pixel group RG1A, FIG. 30 shows a plurality of pixels included in the third pixel group RG1B, FIG. 31 shows a plurality of pixels included in the fourth pixel group RG2A, and FIG. 32 shows a plurality of pixels included in the fifth pixel group RG2B.

Referring to FIG. 29, on a plane parallel to the first direction D1 and the second direction D2, a central portion of the micro-lens 307 shared by the plurality of pixels PXA and PXB included in the second pixel group RG1A may be misaligned such that the central portion of the micro-lens 307 does not overlap with the central portion between the plurality of pixels PXA and PXB. The central portion of the micro-lens 307 may be shifted to the left with respect to the central portion between the plurality of pixels PXA and PXB.

Although not shown in the drawings, as shown in FIGS. 6 to 8, the central portion of the micro-lens 307 may be spaced apart from the central portion between the plurality of pixels PXA and PXB by the first interval LD11 along the first direction D1.

In the first pixel PXA and the second pixel PXB that are included in the second pixel group RG1A and share one micro-lens 307, the guide pattern 317 may include the first guide pattern 317A of the guide pattern 317 overlapping the first pixel isolation pattern 450A of the pixel isolation pattern 450 and a second guide pattern 317D11 extending from the first guide pattern 317A toward a central portion between the first pixel PXA and the second pixel PXB to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317D11 of the guide pattern 317 that extends from the first guide pattern 317A may have a second width W2. The second guide pattern 317D11 may be disposed to be shifted to the right of the second pixel isolation pattern 450B of the pixel isolation pattern 450 along the first direction D1, and the second guide pattern 317D11 may obliquely extend so as to further overlap the second pixel isolation pattern 450B as a distance between the second guide pattern 317D11 and the first guide pattern 317A increases. An obtuse angle formed by the first guide pattern 317A and the second guide pattern 317D11 may be a first angle θ1.

The second guide pattern 317D11 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317D11 of the guide pattern 317 may reflect light that is obliquely incident so that the light is focused close to the upper surface of the substrate 400.

Referring to FIG. 30, on a plane parallel to the first direction D1 and the second direction D2, a central portion of the micro-lens 307 shared by the plurality of pixels PXA and PXB included in the third pixel group RG1B may be misaligned such that the central portion of the micro-lens 307 does not overlap with the central portion between the plurality of pixels PXA and PXB. The central portion of the micro-lens 307 may be shifted to the right with respect to the central portion between the plurality of pixels PXA and PXB.

Although not shown in the drawings, as shown in FIGS. 9 to 11, the central portion of the micro-lens 307 may be spaced apart from the central portion between the plurality of pixels PXA and PXB by the first interval LD12 along the first direction D1.

In the first pixel PXA and the second pixel PXB that are included in the third pixel group RG1B and share one micro-lens 307, the guide pattern 317 may include the first guide pattern 317A of the guide pattern 317 overlapping the first pixel isolation pattern 450A of the pixel isolation pattern 450 and a second guide pattern 317D12 extending from the first guide pattern 317A toward a central portion between the first pixel PXA and the second pixel PXB to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317D12 of the guide pattern 317 that extends from the first guide pattern 317A may have a second width W2. The second guide pattern 317D12 may be disposed to be shifted to the left of the second pixel isolation pattern 450B of the pixel isolation pattern 450 along the first direction D1, and the second guide pattern 317D12 may obliquely extend so as to further overlap the second pixel isolation pattern 450B as a distance between the second guide pattern 317D12 and the first guide pattern 317A increases. An obtuse angle formed by the first guide pattern 317A and the second guide pattern 317D12 may be a first angle θ1.

The second guide pattern 317D12 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317D12 of the guide pattern 317 may reflect light that is obliquely incident so that the light is focused close to the upper surface of the substrate 400.

Referring to FIG. 31, on a plane parallel to the first direction D1 and the second direction D2, a central portion of the micro-lens 307 shared by the plurality of pixels PXA and PXB included in the fourth pixel group RG2A may be misaligned such that the central portion of the micro-lens 307 does not overlap with the central portion between the plurality of pixels PXA and PXB. The central portion of the micro-lens 307 may be shifted to the left with respect to the central portion between the plurality of pixels PXA and PXB.

Although not shown in the drawings, as shown in FIGS. 12 to 14, the central portion of the micro-lens 307 may be spaced apart from the central portion between the plurality of pixels PXA and PXB by the second interval LD21 along the first direction D1.

In the first pixel PXA and the second pixel PXB that are included in the second pixel group RG1A and share one micro-lens 307, the guide pattern 317 may include the first guide pattern 317A of the guide pattern 317 overlapping the first pixel isolation pattern 450A of the pixel isolation pattern 450 and a second guide pattern 317D21 extending from the first guide pattern 317A toward a central portion between the first pixel PXA and the second pixel PXB to overlap at least a portion of the second pixel isolation pattern 450B of the pixel isolation pattern 450.

The first guide pattern 317A of the guide pattern 317 overlapping the first pixel isolation pattern 450A of the pixel isolation pattern 450 may have a first width W1, and the second guide pattern 317D21 of the guide pattern 317 that extends from the first guide pattern 317A may have a third width. The second guide pattern 317D21 may be disposed to be shifted to the right of the second pixel isolation pattern 450B of the pixel isolation pattern 450 along the first direction D1, and the second guide pattern 317D21 may that is obliquely extend so as to further overlap the second pixel isolation pattern 450B as a distance between the second guide pattern 317D21 and the first guide pattern 317A increases. An obtuse angle formed by the first guide pattern 317A and the second guide pattern 317D21 may be a second angle θ2, and the second angle θ2 may be larger than the first angle θ1.

The second guide pattern 317D21 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317D21 of the guide pattern 317 may reflect light that is obliquely incident so that the light is focused close to the upper surface of the substrate 400.

Referring to FIG. 32, on a plane parallel to the first direction D1 and the second direction D2, a central portion of the micro-lens 307 shared by the plurality of pixels PXA and PXB included in the fifth pixel group RG2B may be misaligned such that the central portion of the micro-lens 307 does not overlap with the central portion between the plurality of pixels PXA and PXB. The central portion of the micro-lens 307 may be shifted to the right with respect to the central portion between the plurality of pixels PXA and PXB.

Although not shown in the drawings, as shown in FIGS. 15 to 17, the central portion of the micro-lens 307 may be spaced apart from the central portion between the plurality of pixels PXA and PXB by the second interval LD22 along the first direction D1.

In the first pixel PXA and the second pixel PXB that are included in the fifth pixel group RG2B and share one micro-lens 307, the guide pattern 317 may include the first guide pattern 317A of the guide pattern 317 overlapping the first pixel isolation pattern 450A of the pixel isolation pattern 450 and a second guide pattern 317D22 extending from the first guide pattern 317A toward a central portion between the first pixel PXA and the second pixel PXB to overlap at least a portion of the second pixel isolation pattern 450B of the pixel isolation pattern 450.

The first guide pattern 317A of the guide pattern 317 that overlaps the first pixel isolation pattern 450A of the pixel isolation pattern 450 may have a first width W1, and the second guide pattern 317D22 of the guide pattern 317 that extends from the first guide pattern 317A may have a third width W3. The second guide pattern 317D22 may be disposed to be shifted to the left of the second pixel isolation pattern 450B of the pixel isolation pattern 450 along the first direction D1, and the second guide pattern 317D22 may obliquely extend so as to further overlap the second pixel isolation pattern 450B as a distance between the second guide pattern 317D22 and the first guide pattern 317A increases. An obtuse angle formed by the first guide pattern 317A and the second guide pattern 317D22 may be a second angle θ2, and the second angle θ2 may be larger than the first angle θ1.

The second guide pattern 317D22 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317D22 of the guide pattern 317 may reflect light that is obliquely incident so that the light is focused close to the upper surface of the substrate 400.

According to the present embodiment, the second guide pattern 317D22 may reflect light that is obliquely incident toward the micro-lens 307 so that the light is incident on the photoelectric conversion region 410 and the light is focused close to the upper surface of the substrate 400. Therefore, a decrease in the efficiency of the pixel PX may be prevented by changing the optical path.

According to the embodiment, the image sensor 100 may include the second guide pattern extending toward a central portion of the plurality of pixels sharing the micro-lens, and a width and an extending slope of the second guide pattern may be differently adjusted depending on a region of the image sensor 100 so that the second guide pattern corrects a difference in intensity and a difference in a focal position of light incident on the photoelectric conversion region 410 that may occur according to a difference in an incident angle of light incident according to a position of the image sensor 100.

According to the embodiment, the difference in the incident angle of light incident according to the position of the image sensor 100 may be corrected using the second guide pattern, so that the decrease in the efficiency of the pixel PX is prevented by changing the optical path.

Many features of the image sensors according to the embodiments described above are all applicable to the image sensor according to the present embodiment.

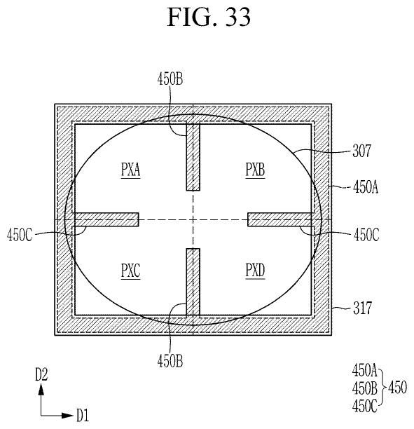

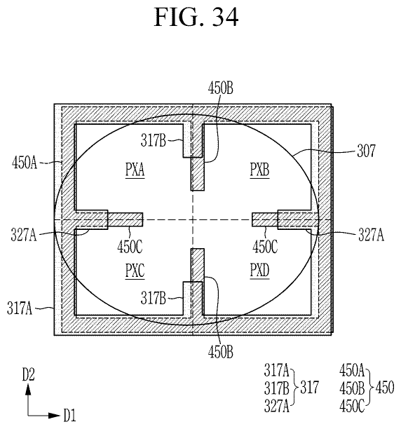

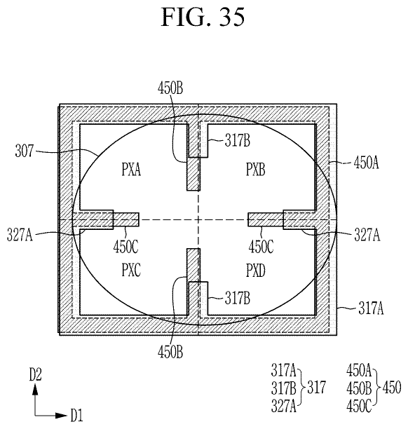

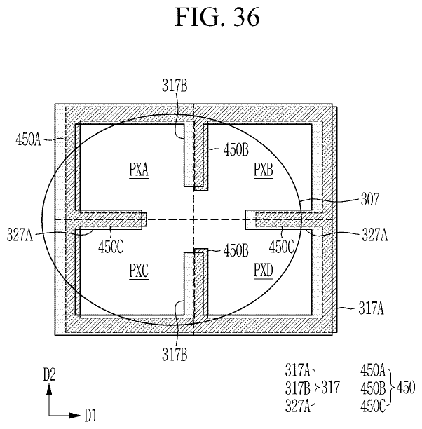

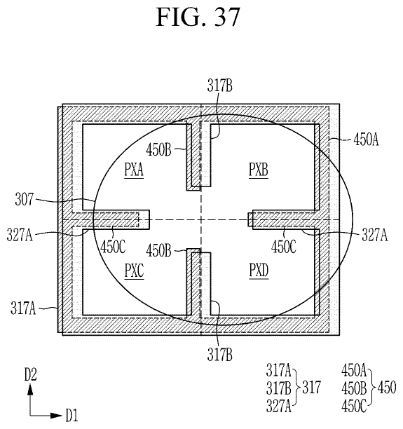

An image sensor according to another embodiment will be described with reference to FIGS. 33 to 37. FIGS. 33 to 37 are enlarged views of a portion of FIG. 2. FIG. 33 shows a plurality of pixels included in the first pixel group RG0, FIG. 34 shows a plurality of pixels included in the second pixel group RG1A, FIG. 35 shows a plurality of pixels included in the third pixel group RG1B, FIG. 36 shows a plurality of pixels included in the fourth pixel group RG2A, and FIG. 37 shows a plurality of pixels included in the fifth pixel group RG2B.

Referring to FIGS. 33 to 37, the image sensor according to the present embodiment is similar to the image sensors according to the embodiments described above.

Unlike the image sensors according to the embodiments described above, in the image sensor according to the present embodiment, a plurality of pixels sharing one micro-lens 307 may include four adjacent pixels PXA, PXB, PXC, and PXD.

The pixel isolation pattern 450 may include a first pixel isolation pattern 450A disposed at an outer portion to surround the four pixels PXA, PXB, PXC, and PXD, a second pixel isolation pattern 450B extending from the first pixel isolation pattern 450A along the second direction D2 to be disposed between the first pixel PXA and the second pixel PXB and between the third pixel PXC and the fourth pixel PXD, and a third pixel isolation pattern 450C extending from the first pixel isolation pattern 450A along the first direction D1 to be disposed between the first pixel PXA and the third pixel PXC and between the second pixel PXB and the fourth pixel PXD.

Referring to FIG. 33, in the four pixels PXA, PXB, PXC, and PXD that are included in the first pixel group RG0 disposed at a central portion of the image sensor 100 and share one micro-lens 307, the guide pattern 317 may overlap the first pixel isolation pattern 450A of the pixel isolation pattern 450, and may not overlap the second pixel isolation pattern 450B and the third pixel isolation pattern 450C of the pixel isolation pattern 450.

Referring to FIG. 34, on a plane parallel to the first direction D1 and the second direction D2, a central portion of the micro-lens 307 shared by the plurality of pixels PXA, PXB, PXC, and PXD included in the second pixel group RG1A may be misaligned such that the central portion of the micro-lens 307 does not overlap with a central portion between the plurality of pixels PXA, PXB, PXC, and PXD. The central portion of the micro-lens 307 may be shifted to the left with respect to the central portion of the plurality of pixels PXA, PXB, PXC, and PXD.

Although not shown in the drawings, as shown in FIGS. 6 to 8, the central portion of the micro-lens 307 may be spaced apart from the central portion of the plurality of pixels PXA, PXB, PXC, and PXD by the first interval LD11 along the first direction D1.

In the plurality of pixels PXA, PXB, PXC, and PXD that are included in the second pixel group RG1A and share one micro-lens 307, the guide pattern 317 may include a first guide pattern 317A that overlaps the first pixel isolation pattern 450A of the pixel isolation pattern 450, a second guide pattern 317B extending from the first guide pattern 317A toward the central portion of the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317B of the guide pattern 317 that extends from the first guide pattern 317A may have a second width W2. Similarly, the third guide pattern 327A that overlaps the third pixel isolation pattern 450C may have the second width W2.

The second guide pattern 317B and the third guide pattern 327A of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B and the third guide pattern 327A of the guide pattern 317 may reflect light that is obliquely incident so that the light is focused close to the upper surface of the substrate 400.

Referring to FIG. 35, on a plane parallel to the first direction D1 and the second direction D2, a central portion of the micro-lens 307 shared by the plurality of pixels PXA, PXB, PXC, and PXD included in the third pixel group RG1B may be misaligned such that the central portion of the micro-lens 307 does not overlap with the central portion of the plurality of pixels PXA, PXB, PXC, and PXD. The central portion of the micro-lens 307 may be shifted to the right with respect to the central portion of the plurality of pixels PXA, PXB, PXC, and PXD.

Although not shown in the drawings, as shown in FIGS. 9 to 11, the central portion of the micro-lens 307 may be spaced apart from the central portion between the plurality of pixels PXA, PXB, PXC, and PXD by the first interval LD12 along the first direction D1.

In the plurality of pixels PXA, PXB, PXC, and PXD that are included in the third pixel group RG1B and share one micro-lens 307, the guide pattern 317 may include a first guide pattern 317A that overlaps the first pixel isolation pattern 450A of the pixel isolation pattern 450, a second guide pattern 317B extending from the first guide pattern 317A toward the central portion of the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317B of the guide pattern 317 that extends from the first guide pattern 317A may have a second width W2. Similarly, the third guide pattern 327A that overlaps the third pixel isolation pattern 450C may have the second width W2.

The second guide pattern 317B and the third guide pattern 327A of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B and the third guide pattern 327A of the guide pattern 317 may reflect light that is obliquely incident so that the light is focused close to the upper surface of the substrate 400.

Referring to FIG. 36, on a plane parallel to the first direction D1 and the second direction D2, a central portion of the micro-lens 307 shared by the plurality of pixels PXA, PXB, PXC, and PXD included in the fourth pixel group RG2A may be misaligned such that the central portion of the micro-lens 307 does not overlap with the central portion between the plurality of pixels PXA, PXB, PXC, and PXD. The central portion of the micro-lens 307 may be shifted to the left with respect to the central portion of the plurality of pixels PXA, PXB, PXC, and PXD.

Although not shown in the drawings, as shown in FIGS. 12 to 14, the central portion of the micro-lens 307 may be spaced apart from the central portion between the plurality of pixels PXA, PXB, PXC, and PXD by the second interval LD21 along the first direction D1.

In the pixels PXA, PXB, PXC, and PXD that are included in the second pixel group RG1A and share one micro-lens 307, the guide pattern 317 may include a first guide pattern 317A that overlaps the first pixel isolation pattern 450A of the pixel isolation pattern 450, a second guide pattern 317B extending from the first guide pattern 317A toward the central portion between the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317B of the guide pattern 317 that extends from the first guide pattern 317A may have a third width W3. Similarly, the third guide pattern 327A that overlaps the third pixel isolation pattern 450C may have the third width W3. The third width W3 may be larger than the second width W2.

The second guide pattern 317B and the third guide pattern 327A of the guide pattern 317 may reflect light that is obliquely incident toward the micro-lens 307 so that the light is incident on the photoelectric conversion region 410.

In addition, light incident that is obliquely toward the micro-lens 307 may normally be focused at a relatively high position from an upper surface of the substrate 400, but the second guide pattern 317B and the third guide pattern 327A of the guide pattern 317 may reflect light that is obliquely incident so that the light is focused close to the upper surface of the substrate 400.

Referring to FIG. 37, on a plane parallel to the first direction D1 and the second direction D2, a central portion of the micro-lens 307 shared by the plurality of pixels PXA, PXB, PXC, and PXD included in the fifth pixel group RG2B may be misaligned such that the central portion of the micro-lens 307 does not overlap with the central portion between the pixels PXA, PXB, PXC, and PXD. The central portion of the micro-lens 307 may be shifted to the right with respect to the central portion of the plurality of pixels PXA, PXB, PXC, and PXD.

Although not shown in the drawings, as shown in FIGS. 15 to 17, the central portion of the micro-lens 307 may be spaced apart from the central portion between the plurality of pixels PXA, PXB, PXC, and PXD by the second interval LD22 along the first direction D1.

In the plurality of pixels PXA, PXB, PXC, and PXD that are included in the fifth pixel group RG2B and share one micro-lens 307, the guide pattern 317 may include a first guide pattern 317A that overlaps the first pixel isolation pattern 450A of the pixel isolation pattern 450, a second guide pattern 317B extending from the first guide pattern 317A toward the central portion between the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317B of the guide pattern 317 that extends from the first guide pattern 317A may have a third width W3. Similarly, the third guide pattern 327A that overlaps the third pixel isolation pattern 450C may have the third width W3. The third width W3 may be larger than the second width W2.

The second guide pattern 317B and the third guide pattern 327A of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B and the third guide pattern 327A of the guide pattern 317 may reflect light that is obliquely incident so that the light is focused close to the upper surface of the substrate 400.

According to the present embodiment, the second guide pattern 317B and the third guide pattern 327A of the guide pattern 317 may reflect light that is obliquely incident toward the micro-lens 307 so that the light is incident on the photoelectric conversion region 410 and the light is focused close to the upper surface of the substrate 400. Therefore, a decrease in the efficiency of the pixel PX may be prevented by changing the optical path.

According to the embodiment, the image sensor 100 may include the second guide pattern extending toward a central portion of the plurality of pixels sharing the micro-lens, and a width of the second guide pattern may be differently adjusted depending on a region of the image sensor 100 so that the second guide pattern corrects a difference in intensity and a difference in a focal position of light incident on the photoelectric conversion region 410 that may occur according to a difference in an incident angle of light incident according to a position of the image sensor 100.

According to the embodiment, the difference in the incident angle of light incident according to the position of the image sensor 100 may be corrected using the second guide pattern, so that the decrease in the efficiency of the pixel PX is prevented by changing the optical path.

Many features of the image sensors according to the embodiments described above are all applicable to the image sensor according to the present embodiment.

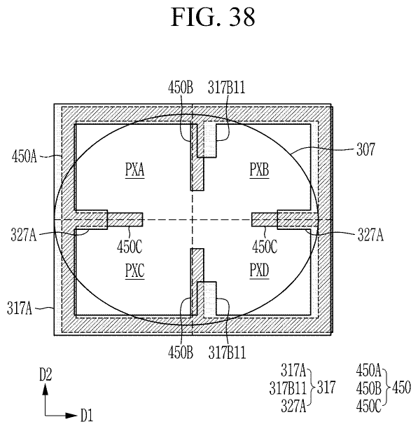

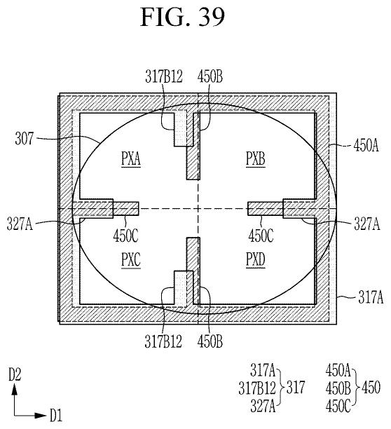

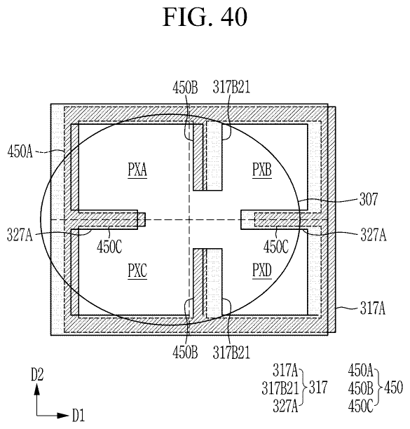

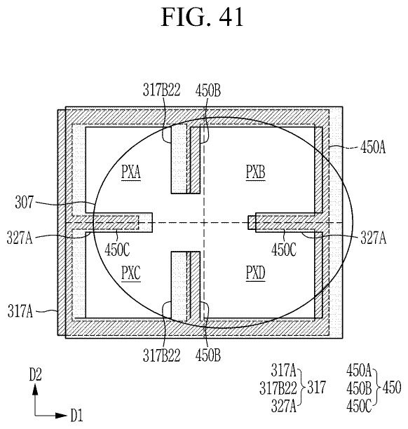

An image sensor according to another embodiment will be described with reference to FIGS. 38 to 41 together with FIG. 33. FIGS. 38 to 41 are enlarged views of a portion of FIG. 2. FIG. 38 shows a plurality of pixels included in the second pixel group RG1A, FIG. 39 shows a plurality of pixels included in the third pixel group RG1B, FIG. 40 shows a plurality of pixels included in the fourth pixel group RG2A, and FIG. 41 shows a plurality of pixels included in the fifth pixel group RG2B.

Referring to FIG. 38, on a plane parallel to the first direction D1 and the second direction D2, a central portion of the micro-lens 307 shared by the plurality of pixels PXA, PXB, PXC, and PXD included in the second pixel group RG1A may be misaligned such that the central portion of the micro-lens 307 does not overlap with a central portion between the plurality of pixels PXA, PXB, PXC, and PXD. The central portion of the micro-lens 307 may be shifted to the left with respect to the central portion of the plurality of pixels PXA, PXB, PXC, and PXD.

Although not shown in the drawings, as shown in FIGS. 6 to 8, the central portion of the micro-lens 307 may be spaced apart from the central portion of the plurality of pixels PXA, PXB, PXC, and PXD by the first interval LD11 along the first direction D1.

In the plurality of pixels PXA, PXB, PXC, and PXD that are included in the second pixel group RG1A and share one micro-lens 307, the guide pattern 317 may include a first guide pattern 317A that overlaps the first pixel isolation pattern 450A of the pixel isolation pattern 450, a second guide pattern 317B11 extending from the first guide pattern 317A toward the central portion of the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317B11 of the guide pattern 317 that extends from the first guide pattern 317A may have a second width W2.

The second guide pattern 317B11 may be disposed to be shifted to the right of the second pixel isolation pattern 450B of the pixel isolation pattern 450 along the first direction D1. A portion of the second guide pattern 317B11 may not overlap the second pixel isolation pattern 450B, and the portion of the second guide pattern 317B11 that does not overlap the second pixel isolation pattern 450B may have the first width W1 along the first direction D1.

The second guide pattern 317B11 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B11 of the guide pattern 317 may reflect light that is obliquely incident so that the light is focused close to the upper surface of the substrate 400.

Referring to FIG. 39, on a plane parallel to the first direction D1 and the second direction D2, a central portion of the micro-lens 307 shared by the plurality of pixels PXA, PXB, PXC, and PXD included in the third pixel group RG1B may be misaligned such that the central portion of the micro-lens 307 does not overlap with the central portion of the plurality of pixels PXA, PXB, PXC, and PXD. The central portion of the micro-lens 307 may be shifted to the right with respect to the central portion of the plurality of pixels PXA, PXB, PXC, and PXD.

Although not shown in the drawings, as shown in FIGS. 9 to 11, the central portion of the micro-lens 307 may be spaced apart from the central portion between the plurality of pixels PXA, PXB, PXC, and PXD by the first interval LD12 along the first direction D1.

In the plurality of pixels PXA, PXB, PXC, and PXD that are included in the third pixel group RG1B and share one micro-lens 307, the guide pattern 317 may include a first guide pattern 317A that overlaps the first pixel isolation pattern 450A of the pixel isolation pattern 450, a second guide pattern 317B12 extending from the first guide pattern 317A toward the central portion of the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317B12 of the guide pattern 317 that extends from the first guide pattern 317A may have a second width W2.

The second guide pattern 317B12 may be disposed to be shifted to the left of the second pixel isolation pattern 450B of the pixel isolation pattern 450 along the first direction D1. A portion of the second guide pattern 317B12 may not overlap the second pixel isolation pattern 450B, and the portion of the second guide pattern 317B12 that does not overlap the second pixel isolation pattern 450B may have the first width W1 along the first direction D1.

The second guide pattern 317B12 of the guide pattern 317 may reflect light that is obliquely incident toward the micro-lens 307 so that the light is incident on the photoelectric conversion region 410.

In addition, light incident that is obliquely toward the micro-lens 307 may normally be focused at a relatively high position from an upper surface of the substrate 400, but the second guide pattern 317B12 of the guide pattern 317 may reflect light that is obliquely incident so that the light is focused close to the upper surface of the substrate 400.

Referring to FIG. 40, on a plane parallel to the first direction D1 and the second direction D2, a central portion of the micro-lens 307 shared by the plurality of pixels PXA, PXB, PXC, and PXD included in the fourth pixel group RG2A may be misaligned such that the central portion of the micro-lens 307 does not overlap with the central portion between the plurality of pixels PXA, PXB, PXC, and PXD. The central portion of the micro-lens 307 may be shifted to the left with respect to the central portion of the plurality of pixels PXA, PXB, PXC, and

Although not shown in the drawings, as shown in FIGS. 12 to 14, the central portion of the micro-lens 307 may be spaced apart from the central portion between the plurality of pixels PXA, PXB, PXC, and PXD by the second interval LD21 along the first direction D1.

In the pixels PXA, PXB, PXC, and PXD that are included in the second pixel group RG1A and share one micro-lens 307, the guide pattern 317 may include a first guide pattern 317A that overlaps the first pixel isolation pattern 450A of the pixel isolation pattern 450, a second guide pattern 317B21 extending from the first guide pattern 317A toward the central portion between the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317B21 of the guide pattern 317 that extends from the first guide pattern 317A may have a third width W3. The third width W3 may be larger than the second width W2.

The second guide pattern 317B21 may be disposed to be shifted to the right of the second pixel isolation pattern 450B of the pixel isolation pattern 450 along the first direction D1. A portion of the second guide pattern 317B21 may not overlap the second pixel isolation pattern 450B, and the portion of the second guide pattern 317B21 that does not overlap the second pixel isolation pattern 450B may have the second width W2 along the first direction D1. The second width W2 may be larger than the first width W1.

The second guide pattern 317B21 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B21 of the guide pattern 317 may reflect light that is obliquely incident so that the light is focused close to the upper surface of the substrate 400.

Referring to FIG. 41, on a plane parallel to the first direction D1 and the second direction D2, a central portion of the micro-lens 307 shared by the plurality of pixels PXA, PXB, PXC, and PXD included in the fifth pixel group RG2B may be misaligned such that the central portion of the micro-lens 307 does not overlap with the central portion between the pixels PXA, PXB, PXC, and PXD. The central portion of the micro-lens 307 may be shifted to the right with respect to the central portion of the plurality of pixels PXA, PXB, PXC, and PXD.

Although not shown in the drawings, as shown in FIGS. 15 to 17, the central portion of the micro-lens 307 may be spaced apart from the central portion between the plurality of pixels PXA, PXB, PXC, and PXD by the second interval LD22 along the first direction D1.

In the plurality of pixels PXA, PXB, PXC, and PXD that are included in the fifth pixel group RG2B and share one micro-lens 307, the guide pattern 317 may include a first guide pattern 317A that overlaps the first pixel isolation pattern 450A of the pixel isolation pattern 450, a second guide pattern 317B22 extending from the first guide pattern 317A toward the central portion between the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317B22 of the guide pattern 317 that extends from the first guide pattern 317A may have a third width W3. The third width W3 may be greater than the second width W2.

The second guide pattern 317B22 may be disposed to be shifted to the left of the second pixel isolation pattern 450B of the pixel isolation pattern 450 along the first direction D1. A portion of the second guide pattern 317B22 may not overlap the second pixel isolation pattern 450B, and the portion of the second guide pattern 317B22 that does not overlap the second pixel isolation pattern 450B may have the second width W2 along the first direction D1. The second width W2 may be greater than the first width W1.

The second guide pattern 317B22 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317B22 of the guide pattern 317 may reflect light that is obliquely incident so that the light is focused close to the upper surface of the substrate 400.

According to the present embodiment, the second guide pattern 317B22 of the guide pattern 317 may reflect light that is obliquely incident toward the micro-lens 307 so that the light is incident on the photoelectric conversion region 410 and the light is focused close to the upper surface of the substrate 400. Therefore, a decrease in the efficiency of the pixel PX may be prevented by changing the optical path.

According to the embodiment, the image sensor 100 may include the second guide pattern extending toward a central portion of the plurality of pixels sharing the micro-lens, and a width and a position of the second guide pattern may be differently adjusted depending on a region of the image sensor 100 so that the second guide pattern corrects a difference in intensity and a difference in a focal position of light incident on the photoelectric conversion region 410 that may occur according to a difference in an incident angle of light incident according to a position of the image sensor 100.

According to the embodiment, the difference in the incident angle of light incident according to the position of the image sensor 100 may be corrected using the second guide pattern, so that the decrease in the efficiency of the pixel PX is prevented by changing the optical path.

Many features of the image sensors according to the embodiments described above are all applicable to the image sensor according to the present embodiment.

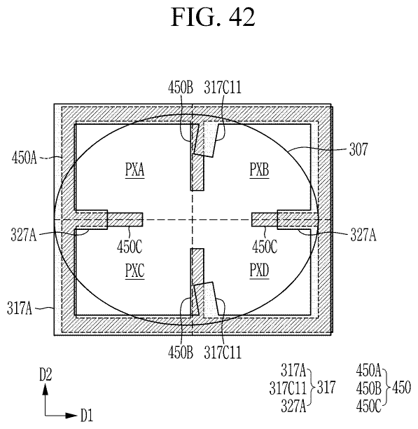

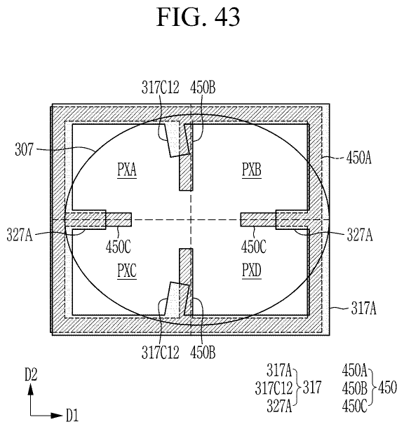

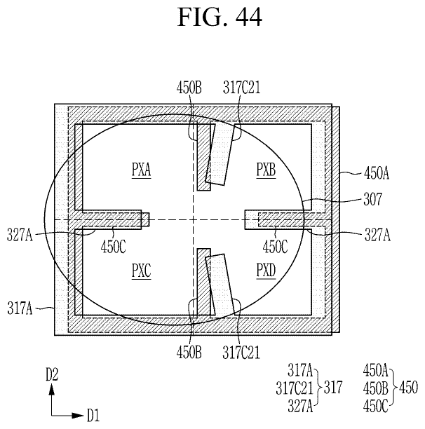

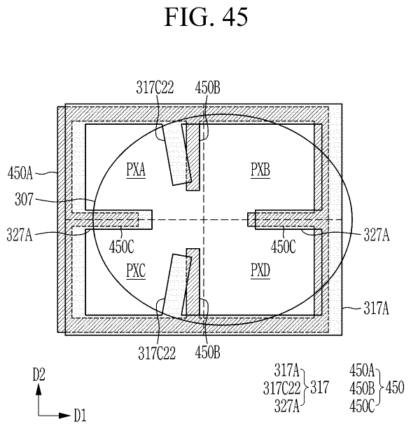

An image sensor according to another embodiment will be described with reference to FIGS. 42 to 45 together with FIG. 33. FIGS. 42 to 45 are enlarged views of a portion of FIG. 2. FIG. 42 shows a plurality of pixels included in the second pixel group RG1A, FIG. 43 shows a plurality of pixels included in the third pixel group RG1B, FIG. 44 shows a plurality of pixels included in the fourth pixel group RG2A, and FIG. 45 shows a plurality of pixels included in the fifth pixel group RG2B.

Referring to FIG. 42, on a plane parallel to the first direction D1 and the second direction D2, a central portion of the micro-lens 307 shared by the plurality of pixels PXA, PXB, PXC, and PXD included in the second pixel group RG1A may be misaligned such that the central portion of the micro-lens 307 does not overlap with a central portion between the plurality of pixels PXA, PXB, PXC, and PXD. The central portion of the micro-lens 307 may be shifted to the left with respect to the central portion of the plurality of pixels PXA, PXB, PXC, and PXD.

Although not shown in the drawings, as shown in FIGS. 6 to 8, the central portion of the micro-lens 307 may be spaced apart from the central portion of the plurality of pixels PXA, PXB, PXC, and PXD by the first interval LD11 along the first direction D1.

In the plurality of pixels PXA, PXB, PXC, and PXD that are included in the second pixel group RG1A and share one micro-lens 307, the guide pattern 317 may include a first guide pattern 317A that overlaps the first pixel isolation pattern 450A of the pixel isolation pattern 450, a second guide pattern 317C11 extending from the first guide pattern 317A toward the central portion of the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317C11 of the guide pattern 317 that extends from the first guide pattern 317A may have a second width W2. The second guide pattern 317C11 may be disposed to be shifted to the right of the second pixel isolation pattern 450B of the pixel isolation pattern 450 along the first direction D1, and the second guide pattern 317C11 may obliquely extend so as to further overlap the second pixel isolation pattern 450B as a distance between the second guide pattern 317C11 and the first guide pattern 317A increases.

The second guide pattern 317C11 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317C11 of the guide pattern 317 may reflect light that is obliquely incident so that the light is focused close to the upper surface of the substrate 400.

Referring to FIG. 43, on a plane parallel to the first direction D1 and the second direction D2, a central portion of the micro-lens 307 shared by the plurality of pixels PXA, PXB, PXC, and PXD included in the third pixel group RG1B may be misaligned such that the central portion of the micro-lens 307 does not overlap with the central portion of the plurality of pixels PXA, PXB, PXC, and PXD. The central portion of the micro-lens 307 may be shifted to the right with respect to the central portion of the plurality of pixels PXA, PXB, PXC, and PXD.

Although not shown in the drawings, as shown in FIGS. 9 to 11, the central portion of the micro-lens 307 may be spaced apart from the central portion between the plurality of pixels PXA, PXB, PXC, and PXD by the first interval LD12 along the first direction D1.

In the plurality of pixels PXA, PXB, PXC, and PXD that are included in the third pixel group RG1B and share one micro-lens 307, the guide pattern 317 may include a first guide pattern 317A that overlaps the first pixel isolation pattern 450A of the pixel isolation pattern 450, a second guide pattern 317C12 extending from the first guide pattern 317A toward the central portion of the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317C12 of the guide pattern 317 that extends from the first guide pattern 317A may have a second width W2. The second guide pattern 317C12 may be disposed to be shifted to the left of the second pixel isolation pattern 450B of the pixel isolation pattern 450 along the first direction D1, and the second guide pattern 317C12 may obliquely extend so as to further overlap the second pixel isolation pattern 450B as a distance between the second guide pattern 317C12 and the first guide pattern 317A increases.

The second guide pattern 317C12 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317C12 of the guide pattern 317 may reflect light that is obliquely incident so that the light is focused close to the upper surface of the substrate 400.

Referring to FIG. 44, on a plane parallel to the first direction D1 and the second direction D2, a central portion of the micro-lens 307 shared by the plurality of pixels PXA, PXB, PXC, and PXD included in the fourth pixel group RG2A may be misaligned such that the central portion of the micro-lens 307 does not overlap with the central portion between the plurality of pixels PXA, PXB, PXC, and PXD. The central portion of the micro-lens 307 may be shifted to the left with respect to the central portion of the plurality of pixels PXA, PXB, PXC, and

Although not shown in the drawings, as shown in FIGS. 12 to 14, the central portion of the micro-lens 307 may be spaced apart from the central portion between the plurality of pixels PXA, PXB, PXC, and PXD by the second interval LD21 along the first direction D1.

In the pixels PXA, PXB, PXC, and PXD that are included in the second pixel group RG1A and share one micro-lens 307, the guide pattern 317 may include a first guide pattern 317A that overlaps the first pixel isolation pattern 450A of the pixel isolation pattern 450, a second guide pattern 317C21 extending from the first guide pattern 317A toward the central portion between the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317C21 of the guide pattern 317 that extends from the first guide pattern 317A may have a third width W3. The second guide pattern 317C21 may be disposed to be shifted to the right of the second pixel isolation pattern 450B of the pixel isolation pattern 450 along the first direction D1, and the second guide pattern 317C21 may obliquely extend so as to further overlap the second pixel isolation pattern 450B as a distance between the second guide pattern 317C21 and the first guide pattern 317A increases.

The second guide pattern 317C21 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317C21 of the guide pattern 317 may reflect light that is obliquely incident so that the light is focused close to the upper surface of the substrate 400.

Referring to FIG. 45, on a plane parallel to the first direction D1 and the second direction D2, a central portion of the micro-lens 307 shared by the plurality of pixels PXA, PXB, PXC, and PXD included in the fifth pixel group RG2B may be misaligned such that the central portion of the micro-lens 307 does not overlap with the central portion between the pixels PXA, PXB, PXC, and PXD. The central portion of the micro-lens 307 may be shifted to the right with respect to the central portion of the plurality of pixels PXA, PXB, PXC, and PXD.

Although not shown in the drawings, as shown in FIGS. 15 to 17, the central portion of the micro-lens 307 may be spaced apart from the central portion between the plurality of pixels PXA, PXB, PXC, and PXD by the second interval LD22 along the first direction D1.

In the plurality of pixels PXA, PXB, PXC, and PXD that are included in the fifth pixel group RG2B and share one micro-lens 307, the guide pattern 317 may include a first guide pattern 317A that overlaps the first pixel isolation pattern 450A of the pixel isolation pattern 450, a second guide pattern 317C22 extending from the first guide pattern 317A toward the central portion between the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317C22 of the guide pattern 317 that extends from the first guide pattern 317A may have a third width W3. The second guide pattern 317C22 may be disposed to be shifted to the left of the second pixel isolation pattern 450B of the pixel isolation pattern 450 along the first direction D1, and the second guide pattern 317C22 may obliquely extend so as to further overlap the second pixel isolation pattern 450B as a distance between the second guide pattern 317C22 and the first guide pattern 317A increases. The third width W3 may be larger than the second width W2.

The second guide pattern 317C22 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317C22 of the guide pattern 317 may reflect light that is obliquely incident so that the light is focused close to the upper surface of the substrate 400.

According to the present embodiment, the second guide pattern 317C22 of the guide pattern 317 may reflect light that is obliquely incident toward the micro-lens 307 so that the light is incident on the photoelectric conversion region 410 and the light is focused close to the upper surface of the substrate 400. Therefore, a decrease in the efficiency of the pixel PX may be prevented by changing the optical path.

Many features of the image sensors according to the embodiments described above are all applicable to the image sensor according to the present embodiment.

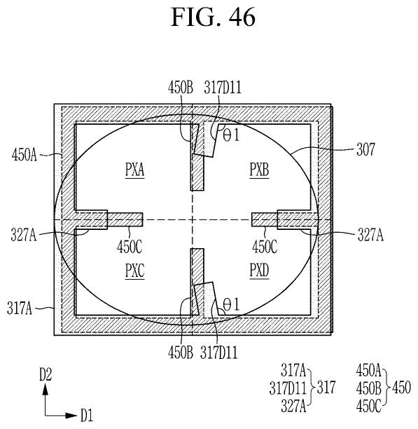

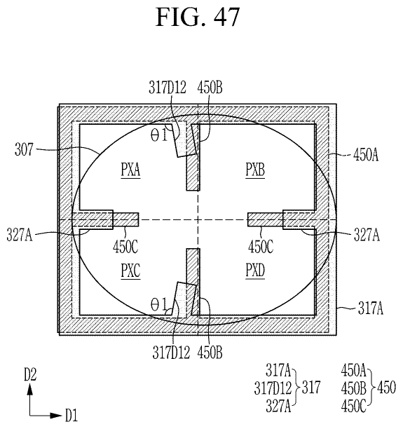

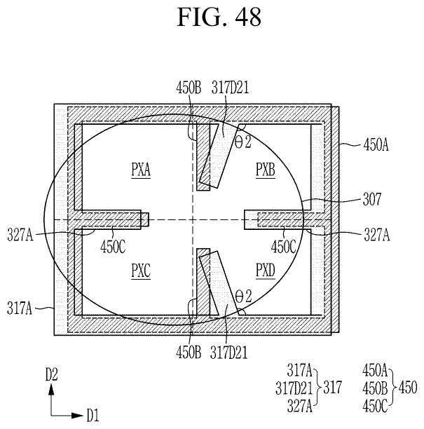

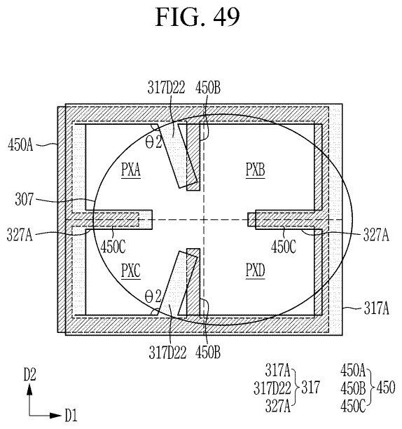

An image sensor according to another embodiment will be described with reference to FIGS. 46 to 49 together with FIG. 33. FIGS. 46 to 49 are enlarged views of a portion of FIG. 2. FIG. 46 shows a plurality of pixels included in the second pixel group RG1A, FIG. 47 shows a plurality of pixels included in the third pixel group RG1B, FIG. 48 shows a plurality of pixels included in the fourth pixel group RG2A, and FIG. 49 shows a plurality of pixels included in the fifth pixel group RG2B.

Referring to FIG. 46, on a plane parallel to the first direction D1 and the second direction D2, a central portion of the micro-lens 307 shared by the plurality of pixels PXA, PXB, PXC, and PXD included in the second pixel group RG1A may be misaligned such that the central portion of the micro-lens 307 does not overlap with a central portion between the plurality of pixels PXA, PXB, PXC, and PXD. The central portion of the micro-lens 307 may be shifted to the left with respect to the central portion of the plurality of pixels PXA, PXB, PXC, and PXD.

Although not shown in the drawings, as shown in FIGS. 6 to 8, the central portion of the micro-lens 307 may be spaced apart from the central portion of the plurality of pixels PXA, PXB, PXC, and PXD by the first interval LD11 along the first direction D1.

In the plurality of pixels PXA, PXB, PXC, and PXD that are included in the second pixel group RG1A and share one micro-lens 307, the guide pattern 317 may include a first guide pattern 317A that overlaps the first pixel isolation pattern 450A of the pixel isolation pattern 450, a second guide pattern 317D11 extending from the first guide pattern 317A toward the central portion of the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317D11 of the guide pattern 317 that extends from the first guide pattern 317A may have a second width W2. The second guide pattern 317D11 may be disposed to be shifted to the right of the second pixel isolation pattern 450B of the pixel isolation pattern 450 along the first direction D1, and the second guide pattern 317D11 may obliquely extend so as to further overlap the second pixel isolation pattern 450B as a distance between the second guide pattern 317D11 and the first guide pattern 317A increases. An obtuse angle formed by the first guide pattern 317A and the second guide pattern 317D11 may be a first angle θ1.

The second guide pattern 317D11 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317D11 of the guide pattern 317 may reflect light that is obliquely incident so that the light is focused close to the upper surface of the substrate 400.

Referring to FIG. 47, on a plane parallel to the first direction D1 and the second direction D2, a central portion of the micro-lens 307 shared by the plurality of pixels PXA, PXB, PXC, and PXD included in the third pixel group RG1B may be misaligned such that the central portion of the micro-lens 307 does not overlap with the central portion of the plurality of pixels PXA, PXB, PXC, and PXD. The central portion of the micro-lens 307 may be shifted to the right with respect to the central portion of the plurality of pixels PXA, PXB, PXC, and PXD.

Although not shown in the drawings, as shown in FIGS. 9 to 11, the central portion of the micro-lens 307 may be spaced apart from the central portion between the plurality of pixels PXA, PXB, PXC, and PXD by the first interval LD12 along the first direction D1.

In the plurality of pixels PXA, PXB, PXC, and PXD that are included in the third pixel group RG1B and share one micro-lens 307, the guide pattern 317 may include a first guide pattern 317A that overlaps the first pixel isolation pattern 450A of the pixel isolation pattern 450, a second guide pattern 317D12 extending from the first guide pattern 317A toward the central portion of the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317D12 of the guide pattern 317 that extends from the first guide pattern 317A may have a second width W2. The second guide pattern 317D12 may be disposed to be shifted to the left of the second pixel isolation pattern 450B of the pixel isolation pattern 450 along the first direction D1, and the second guide pattern 317D12 may obliquely extend so as to further overlap the second pixel isolation pattern 450B as a distance between the second guide pattern 317D12 and the first guide pattern 317A increases. An obtuse angle formed by the first guide pattern 317A and the second guide pattern 317D12 may be a first angle θ1.

The second guide pattern 317D12 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317D12 of the guide pattern 317 may reflect light that is obliquely incident so that the light is focused close to the upper surface of the substrate 400.

Referring to FIG. 48, on a plane parallel to the first direction D1 and the second direction D2, a central portion of the micro-lens 307 shared by the plurality of pixels PXA, PXB, PXC, and PXD included in the fourth pixel group RG2A may be misaligned such that the central portion of the micro-lens 307 does not overlap with the central portion between the plurality of pixels PXA, PXB, PXC, and PXD. The central portion of the micro-lens 307 may be shifted to the left with respect to the central portion of the plurality of pixels PXA, PXB, PXC, and PXD.

Although not shown in the drawings, as shown in FIGS. 12 to 14, the central portion of the micro-lens 307 may be spaced apart from the central portion between the plurality of pixels PXA, PXB, PXC, and PXD by the second interval LD21 along the first direction D1.

In the pixels PXA, PXB, PXC, and PXD that are included in the second pixel group RG1A and share one micro-lens 307, the guide pattern 317 may include a first guide pattern 317A that overlaps the first pixel isolation pattern 450A of the pixel isolation pattern 450, a second guide pattern 317D21 extending from the first guide pattern 317A toward the central portion between the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317D21 of the guide pattern 317 that extends from the first guide pattern 317A may have a third width W3. The second guide pattern 317D21 may be disposed to be shifted to the right of the second pixel isolation pattern 450B of the pixel isolation pattern 450 along the first direction D1, and the second guide pattern 317D21 may obliquely extend so as to further overlap the second pixel isolation pattern 450B as a distance between the second guide pattern 317D21 and the first guide pattern 317A increases. An obtuse angle formed by the first guide pattern 317A and the second guide pattern 317D21 may be a second angle θ2, and the second angle θ2 may be larger than the first angle θ1.

The second guide pattern 317D21 of the guide pattern 317 that overlaps the second pixel isolation pattern 450B of the pixel isolation pattern 450 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317D21 of the guide pattern 317 may reflect light that is obliquely incident so that the light is focused close to the upper surface of the substrate 400.

Referring to FIG. 49, on a plane parallel to the first direction D1 and the second direction D2, a central portion of the micro-lens 307 shared by the plurality of pixels PXA, PXB, PXC, and PXD included in the fifth pixel group RG2B may be misaligned such that the central portion of the micro-lens 307 does not overlap with the central portion between the pixels PXA, PXB, PXC, and PXD. The central portion of the micro-lens 307 may be shifted to the right with respect to the central portion of the plurality of pixels PXA, PXB, PXC, and PXD.

Although not shown in the drawings, as shown in FIGS. 15 to 17, the central portion of the micro-lens 307 may be spaced apart from the central portion between the plurality of pixels PXA, PXB, PXC, and PXD by the second interval LD22 along the first direction D1.

In the plurality of pixels PXA, PXB, PXC, and PXD that are included in the fifth pixel group RG2B and share one micro-lens 307, the guide pattern 317 may include a first guide pattern 317A that overlaps the first pixel isolation pattern 450A of the pixel isolation pattern 450, a second guide pattern 317D22 extending from the first guide pattern 317A toward the central portion between the plurality of pixels PXA, PXB, PXC, and PXD to overlap at least a portion of the second pixel isolation pattern 450B of the pixel isolation pattern 450, and a third guide pattern 327A extending from the first guide pattern 317A along the first direction D1 to overlap the third pixel isolation pattern 450C of the pixel isolation pattern 450.

The first guide pattern 317A of the guide pattern 317 that overlaps the first pixel isolation pattern 450A of the pixel isolation pattern 450 may have a first width W1, and the second guide pattern 317D22 of the guide pattern 317 that extends from the first guide pattern 317A may have a third width W3. The second guide pattern 317D22 may be disposed to be shifted to the left of the second pixel isolation pattern 450B of the pixel isolation pattern 450 along the first direction D1, and the second guide pattern 317D22 may obliquely extend so as to further overlap the second pixel isolation pattern 450B as a distance between the second guide pattern 317D22 and the first guide pattern 317A increases. An obtuse angle formed by the first guide pattern 317A and the second guide pattern 317D22 may be a second angle θ2, and the second angle θ2 may be larger than the first angle θ1.

The second guide pattern 317D22 of the guide pattern 317 may reflect light that is obliquely incident toward the micro-lens 307 so that the light is incident on the photoelectric conversion region 410.

In addition, light that is incident obliquely toward the micro-lens 307 may normally be focused at a relatively high position from an upper surface of the substrate 400, but the second guide pattern 317D22 of the guide pattern 317 may reflect light that is obliquely incident so that the light is focused close to the upper surface of the substrate 400.

According to the present embodiment, the second guide pattern 317D22 of the guide pattern 317 may reflect light that is obliquely incident toward the micro-lens 307 so that the light is incident on the photoelectric conversion region 410 and the light is focused close to the upper surface of the substrate 400. Therefore, a decrease in the efficiency of the pixel PX may be prevented by changing the optical path.

According to the embodiment, the image sensor 100 may include the second guide pattern extending toward a central portion of the plurality of pixels sharing the micro-lens, and a width, a position, and a slope angle of the second guide pattern may be differently adjusted depending on a region of the image sensor 100 so that the second guide pattern corrects a difference in intensity and a difference in a focal position of light incident on the photoelectric conversion region 410 that may occur according to a difference in an incident angle of light incident according to a position of the image sensor 100.

According to the embodiment, the difference in the incident angle of light incident according to the position of the image sensor 100 may be corrected using the second guide pattern, so that the decrease in the efficiency of the pixel PX is prevented by changing the optical path.

Many features of the image sensors according to the embodiments described above are all applicable to the image sensor according to the present embodiment.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

100: image sensor
10: photoelectric conversion layer
20: wiring region
30: light transmission layer
317: guide pattern
400: substrate
410: photoelectric conversion region
450: pixel isolation pattern

What is claimed is:

1. An image sensor comprising:
a substrate;
a plurality of first pixels that are disposed in a first pixel group and share a first micro-lens;
a plurality of second pixels that are disposed in a second pixel group and share a second micro-lens;
a first pixel isolation pattern that is disposed on the substrate and surrounds the plurality of first pixels;
a second pixel isolation pattern that is disposed on the substrate and surrounds the plurality of second pixels;
a first guide pattern that is disposed between the substrate and the first micro-lens and at least partially overlaps the first pixel isolation pattern on a plane parallel to a surface of the substrate;
a second guide pattern that is disposed between the substrate and the first micro-lens and extends toward a central portion between the plurality of first pixels on the plane;
a third guide pattern that is disposed between the substrate and the second micro-lens and at least partially overlaps the second pixel isolation pattern on the plane; and
a fourth guide pattern that is disposed between the substrate and the second micro-lens and extends toward a central portion between the plurality of second pixels on the plane,
wherein the width of the second guide pattern in an extension direction of the second guide pattern and a width of the fourth guide pattern in an extension direction of the fourth guide pattern are different from each other.

2. The image sensor of claim 1, wherein, the width of the first guide pattern in the extension direction of the second guide pattern and the width of the third guide pattern in the extension direction of the fourth guide pattern are the same.

3. The image sensor of claim 2, wherein the second pixel group is disposed closer to an edge of the image sensor than the first pixel group, and the width of the fourth guide pattern in the extension direction of the fourth guide pattern is greater than the width of the second guide pattern in the extension direction of the second guide pattern.

4. The image sensor of claim 3, wherein a central portion of the first micro-lens and the central portion between the plurality of first pixels are spaced apart by a first interval on the plane, a central portion of the second micro-lens and the central portion between the plurality of second pixels are spaced apart by a second interval on the plane, and the first interval and the second interval are different.

5. The image sensor of claim 4, wherein the second interval is greater than the first interval.

6. The image sensor of claim 3, further comprising a third pixel group disposed at a central portion of the image sensor,
wherein the first pixel group is disposed between the second pixel group and the third pixel group.

7. The image sensor of claim 6, further comprising:
a plurality of third pixels that are disposed in the third pixel group and share a third micro-lens;
a third pixel isolation pattern that is disposed on the substrate and surrounds the plurality of third pixels;
a fourth pixel isolation pattern that is disposed on the substrate and extends from the third pixel isolation pattern to be disposed between the plurality of third pixels; and
a fifth guide pattern that is disposed between the substrate and the third micro-lens and overlaps the third pixel isolation pattern,
wherein no guide pattern is disposed between the fourth pixel isolation pattern and the third micro-lens.

8. The image sensor of claim 7, wherein a central portion of the third micro-lens and a central portion between the plurality of third pixels overlap each other on the plane.

9. The image sensor of claim 1, further comprising:
a third pixel isolation pattern that is disposed on the substrate and extends from the first pixel isolation pattern to be disposed between the plurality of first pixels; and
a fourth pixel isolation pattern that is disposed on the substrate and extends from the second pixel isolation pattern to be disposed between the plurality of second pixels,
wherein on the plane, at least a portion of the second guide pattern is disposed at one side of the third pixel isolation pattern and at least a portion of the fourth guide pattern is disposed at one side of the fourth pixel isolation pattern.

10. The image sensor of claim 9, wherein on the plane, a central portion of the first micro-lens is spaced apart from the central portion between the plurality of first pixels in a first direction, on the plane, the portion of the second guide pattern is disposed at a second direction opposite to the first direction of the third pixel isolation pattern, on the plane, a central portion of the second micro-lens is spaced apart from the central portion between the plurality of second pixels in the first direction, and on the plane, the portion of the fourth guide pattern is disposed at the second direction of the fourth pixel isolation pattern.

11. The image sensor of claim 10, wherein the central portion of the first micro-lens and the central portion between the plurality of first pixels are spaced apart by a first interval on the plane, the central portion of the second micro-lens and the central portion between the plurality of second pixels are spaced apart by a second interval on the plane, and the second interval is greater than the first interval.

12. The image sensor of claim 11, wherein on the plane, a second width of at least a portion of the fourth guide pattern is greater than a first width of at least a portion of the second guide pattern.

13. The image sensor of claim 9, wherein on the plane, the second guide pattern obliquely extends to further overlap the third pixel isolation pattern as the second guide pattern extends away from the first guide pattern.

14. The image sensor of claim 13, wherein on the plane, the fourth guide pattern obliquely extends to further overlap the fourth pixel isolation pattern as the fourth guide pattern extends away from the third guide pattern.

15. The image sensor of claim 14, wherein a central portion of the first micro-lens and the central portion between the plurality of first pixels are spaced apart by a first interval on the plane, a central portion of the second micro-lens and the central portion between the plurality of second pixels are spaced apart by a second interval on the plane, and the first interval and the second interval are different.

16. The image sensor of claim 15, wherein the second interval is greater than the first interval.

17. The image sensor of claim 14, wherein a first angle that is an obtuse angle formed by the second guide pattern and the first guide pattern is different from a second angle that is an obtuse angle formed by the fourth guide pattern and the third guide pattern.

18. The image sensor of claim 17, wherein the second pixel group is disposed closer to an edge of the image sensor than the first pixel group, and the second angle is greater than the first angle.

19. The image sensor of claim 18, wherein a central portion of the first micro-lens and the central portion between the plurality of first pixels are spaced apart by a first interval on the plane parallel to the surface of the substrate, a central portion of the second micro-lens and the central portion between the plurality of second pixels are spaced apart by a second interval on the plane parallel to the surface of the substrate, and the first interval and the second interval are different.

20. The image sensor of claim 19, wherein the second interval is greater than the first interval.
